(19) United States
(12) Patent Application Publication
(10) Pub. No.: US 2025/0048848 A1
(43) Pub. Date: Feb. 6, 2025

(54) DISPLAY PANEL AND DISPLAY DEVICE

(71) Applicant: LG Display Co., Ltd., Seoul (KR)

(72) Inventors: Hoseung LEE, Paju-si (KR); JongWon LEE, Paju-si (KR); YoungWook LEE, Paju-si (KR); HeeJung YANG, Paju-si (KR); GiSang HONG, Paju-si (KR); SungKi KIM, Paju-si (KR)

(73) Assignee: LG Display Co., Ltd., Seoul (KR)

(21) Appl. No.: 18/792,178

(22) Filed: Aug. 1, 2024

(30) Foreign Application Priority Data
Aug. 2, 2023 (KR) 10-2023-0100793
Dec. 21, 2023 (KR) 10-2023-0188036

(51) Int. Cl. H10K 59/122; H10K 59/80

(52) U.S. Cl. CPC H10K 59/122; H10K 59/80515; H10K 59/80521

(57) ABSTRACT

A display panel can include a plurality of subpixels disposed on a substrate, an insulating layer disposed on the substrate, the insulating layer including at least one recess portion in at least one subpixel among the plurality of subpixels, an anode electrode disposed on the insulating layer, the anode electrode not overlapping the recess portion, a bank disposed on a portion of an upper surface of the anode electrode and the insulating layer, the bank having an opening in each of the plurality of subpixels, a light emitting layer disposed in the opening, and a cathode electrode disposed on the light emitting layer. Also, each of the light emitting layer and the cathode electrode overlaps with the anode electrode and the recess portion of the insulating layer in the opening, and the cathode electrode has at least one stepped portion in the opening of the bank.

### CROSS-REFERENCE TO RELATED APPLICATION

This application claims priority to Korean Patent Application Nos. 10-2023-0100793 filed on Aug. 2, 2023, and 10-2023-0188036 filed on Dec. 21, 2023, in the Republic of Korea, the entireties of all these applications are hereby incorporated by reference into the present application for all purposes as if fully set forth herein.

### BACKGROUND

### Field

Embodiments of the present disclosure relate to a display panel and a display device.

### Description of Related Art

A display device which displays various information on a screen is a key technology in the era of information and communication technology, and serves to display various information in a display area.

In the display device, excellent display quality and luminous efficiency is desirable. In particular, the importance of luminous efficiency is increasing because the display device is tasked with using limited power according to the development of technology.

The light efficiency of the display device can be determined by light emitting elements included in the display device. The display device including light emitting elements having excellent light efficiency can also have excellent light efficiency. Therefore, as a method for improving the light efficiency of the display device, it can be considered to improve the light efficiency of the light emitting elements.

However, difficulties exist in improving the light efficiency of the light emitting elements and reducing power consumption of the display device. Thus, a need exists for a display device that has a subpixel configuration that can increase luminance and prevent light leakage while also reducing power consumption.

### SUMMARY OF THE DISCLOSURE

Embodiments of the present disclosure are directed to a display panel and display device which have a structure capable of improving light extraction efficiency and simultaneously reducing or preventing a light leakage phenomenon.

Embodiments of the present disclosure are directed to a display panel and display device in which one subpixel includes a plurality of light emitting areas emitting light of the same color, thereby enabling low power driving through high luminance characteristics.

Embodiments of the present disclosure can provide a display panel including a substrate including a plurality of subpixels, an insulating layer disposed on the substrate, and including at least one recess portion in at least one subpixel, an anode electrode disposed on the insulating layer, and not overlapping the recess portion, a bank disposed on a portion of an upper surface of the anode electrode and the insulating layer, and having an opening in each of the plurality of subpixels, a light emitting layer disposed in the opening, and a cathode electrode disposed on the light emitting layer, in which each of the light emitting layer and the cathode electrode overlaps with the anode electrode and the recess portion of the insulating layer in the opening, and has a step in the opening.

Embodiments of the present disclosure can provide a display panel including a substrate including a plurality of subpixels, an insulating layer disposed on the substrate, and including at least one recess portion in at least one subpixel, an anode electrode disposed on the insulating layer, and not overlapping the recess portion, a bank disposed on a portion of an upper surface of the anode electrode and the insulating layer, and having an opening in each of the plurality of subpixels, a light emitting layer disposed in the opening, and a cathode electrode disposed on the light emitting layer, in which each of the light emitting layer and the cathode electrode overlaps with the anode electrode and the recess portion of the insulating layer in the opening, and has a round-shaped depression in the opening.

Embodiments of the present disclosure can provide a display device including a plurality of first non-light emitting areas, a plurality of first light emitting areas surrounding the first non-light emitting areas, a second light emitting area surrounding the first light emitting areas, and a second non-light emitting area surrounding the second light emitting area, in which the plurality of first non-light emitting areas, the plurality of first light emitting areas, the second light emitting area and the second non-light emitting area are disposed in one subpixel, and in which the plurality of first non-light emitting areas, the plurality of first light emitting areas and the second light emitting area are disposed in at least one of an opening of a bank or a boundary of the opening.

According to the embodiments of the present disclosure, as an area corresponding to the opening of a bank includes a recess portion and the recess portion and an anode electrode do not overlap with each other, it is possible to provide a display panel and display device capable of improving light extraction efficiency and simultaneously reducing a light leakage phenomenon.

According to the embodiments of the present disclosure, since one subpixel has a structure which includes a plurality of light emitting areas and a plurality of non-light emitting areas, light efficiency can be improved, and thus, it is possible to provide a display panel and display device capable of low power driving and improved brightness.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, which are briefly described below.

FIG. 1 is a schematic system configuration diagram of a display device according to embodiments of the present disclosure.

FIG. 2 is a plan view illustrating a partial area of a subpixel disposed in the active area of a display panel according to embodiments of the present disclosure.

FIGS. 3A to 3C are diagrams illustrating the light emitting area of a display device according to embodiments of the present disclosure.

FIGS. 4A and 4B are cross-sectional views taken along the line A-B of FIG. 2 according to embodiments of the present disclosure.

FIGS. 5A and 5B are cross-sectional views taken along the line C-D of FIG. 2 according to embodiments of the present disclosure.

FIG. 6A is a cross-sectional view taken along the line a-a′ of FIGS. 3B and 3C according to an embodiment of the present disclosure.

FIG. 6B is a cross-sectional view taken along the line b-b′ of FIGS. 3B and 3C according to an embodiment of the present disclosure.

FIG. 7 is a diagram illustrating a planar structure of four subpixels in a display device according to embodiments of the present disclosure.

FIG. 8 is a diagram illustrating a cross-sectional structure showing opening areas of a bank of four subpixels and a plurality of light emitting areas and a non-light emitting area in a display device according to embodiments of the present disclosure.

FIGS. 9A and 9B are cross-sectional views taken along the line E-F of FIG. 7 according to an embodiment of the present disclosure.

FIGS. 10 to 12 are diagrams each illustrating the planar structure of an area corresponding to the opening of a bank in at least one subpixel disposed in the active area of a display panel according to embodiments of the present disclosure.

FIG. 13 is a plan view illustrating the shape of a mask used to manufacture the planar structure of an area corresponding to the opening of a bank in at least one subpixel disposed in the active area of a display panel according to embodiments of the present disclosure.

FIGS. 14 and 15 are graphs comparing the characteristics of light emitted from one subpixel of a display panel according to embodiments of the present disclosure and the characteristics of light emitted from one subpixel of a display panel according to a comparative example.

FIGS. 16 to 20 are diagrams schematically showing the manufacturing process of a display panel according to embodiments of the present disclosure.

FIGS. 21 and 22 are diagrams each showing the cross-sectional structure of a display panel according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted or may be briefly provided when it is determined that the description can make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to,” “contacts or overlaps,” etc. a second element, it is typically interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it may be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can.”

The features of various embodiments of the present disclosure can be partially or entirely coupled to or combined with each other and can be interlocked and operated in technically various ways, and the embodiments can be carried out independently of or in association with each other.

Hereinafter, various embodiments of the present disclosure will be described in detail with reference to accompanying drawings.

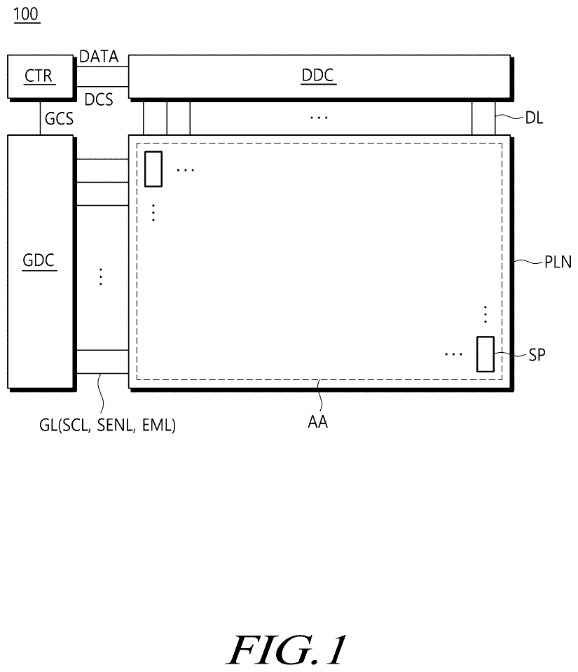

FIG. 1 is a schematic system configuration diagram of a display device according to embodiments of the present disclosure.

The display device according to the embodiments of the present disclosure can include a display device 100, a lighting device, a light emitting device, or the like.

Hereinbelow, for the sake of convenience in explanation, description will be made mainly on the display device 100. However, in addition to the display device 100, the display device can be applied the same or substantially same to various other display devices such as a lighting device and a light emitting device as long as the various other display devices include transistors.

The display device 100 according to the embodiments of the present disclosure can include a display panel PLN which displays an image or outputs light and a driving circuit for driving the display panel PLN.

The display device 100 according to the embodiments of the present disclosure can be a bottom emission type display device in which light is emitted in the direction of a substrate on which light emitting elements are disposed, but the present disclosure is not limited thereto.

Also, the display device 100 according to the embodiments of the present disclosure can be a top emission type in which light is emitted toward a surface opposite to a substrate on which light emitting elements are disposed, or can be a dual emission type in which light generated by light emitting elements is emitted in the direction of a substrate and toward a surface opposite to the substrate.

In the display panel PLN, a plurality of data lines DL and a plurality of gate lines GL can be disposed.

A plurality of subpixels SP which are defined by the plurality of data lines DL and the plurality of gate lines GL can be arranged in a matrix type in the display panel PLN.

In the display panel PLN, the plurality of data lines DL and the plurality of gate lines GL can be disposed to intersect each other.

For example, the plurality of gate lines GL can be arranged in rows or columns, and the plurality of data lines DL can be arranged in columns or rows.

Hereinbelow, for the sake of convenience in explanation, it is assumed that the plurality of gate lines GL are disposed in rows and the plurality of data lines DL are disposed in columns.

In the display panel PLN, other types of signal wirings can be disposed in addition to the plurality of data lines DL and the plurality of gate lines GL, depending on a subpixel structure, etc. In the display panel PLN, a driving power line, a reference power line or a common power line can be further disposed.

The types of signal wirings disposed in the display panel PLN can vary depending on a subpixel structure, etc.

In the present disclosure, a signal wiring can be a concept that includes an electrode to which a signal is applied.

The display panel PLN can include an active area A/A in which an image (a video) is displayed, and a non-active area N/A which is an area outside the active area A/A and in which an image is not displayed.

The non-active area N/A is also referred to as a bezel area.

The plurality of subpixels SP for displaying an image are disposed in the active area A/A.

A pad area to which a data driver DDR is to be electrically connected can be disposed in the non-active area N/A. In addition, a plurality of data link lines for connection between the pad area and the plurality of data lines DL can be disposed in the non-active area N/A.

The plurality of data link lines can be portions of the plurality of data lines DL which extend to the non-active area N/A, or can be separate patterns which are electrically connected to the plurality of data lines DL.

In the non-active area N/A, gate driving-related wirings to transfer a voltage (e.g., a signal) required for gate driving to a gate driver GDR through a pad part to which the data driver DDR is electrically connected can be disposed.

For example, the gate driving-related wirings can include clock wirings for transferring a clock signal, gate power lines for transferring gate voltages (VGH and VGL), gate driving control signal wirings for transferring various control signals necessary to generate a scan signal, etc.

These gate driving-related wirings are disposed in the non-active area N/A, unlike the gate lines GL disposed in the active area A/A.

The driving circuit can include the data driver DDR which drives the plurality of data lines DL, the gate driver GDR which drives the plurality of gate lines GL, and a controller CTR which controls the data driver DDR and the gate driver GDR.

The data driver DDR can drive the plurality of data lines DL by outputting data voltages to the plurality of data lines DL.

The gate driver GDR can drive the plurality of gate lines GL by outputting a scan signal to the plurality of gate lines GL.

The controller CTR can control the driving operations of the data driver DDR and the gate driver GDR by supplying various control signals DCS and GCS necessary for the driving operations of the data driver DDR and the gate driver GDR.

The controller CTR can supply image data DATA to the data driver DDR.

The controller CTR starts scanning according to a timing implemented in each frame.

The controller CTR converts input image data DATA inputted from the outside to be suitable for a data signal format used in the data driver DDR, outputs converted image data, and controls data driving at an appropriate time in correspondence to the scan.

In order to control the data driver DDR and the gate driver GDR, the controller CTR can receive timing signals such as a vertical synchronization signal (Vsync), a horizontal synchronization signal (Hsync), an input data enable (DE: data enable) signal and a clock signal (CLK) from the outside (e.g., a host system), and can generate various control signals.

The controller CTR outputs the generated various control signals to the data driver DDR and gate driver GDR.

For example, in order to control the gate driver GDR, the controller CTR outputs various gate control signals GCS including a gate start pulse (GSP), a gate shift clock (GSC) and a gate output enable signal (GOE).

In order to control the data driver DDR, the controller CTR outputs various data control signals DCS including a source start pulse (SSP), a source sampling clock (SSC) and a source output enable signal (SOE).

The controller CTR can be a timing controller which is used in general display technology.

Alternatively, the controller CTR can be a control device including a timing controller, which is able to further perform other control functions.

The controller CTR can be implemented as a separate component from the data driver DDR.

Alternatively, the controller CTR can be implemented as an integrated circuit by being integrated with the data driver DDR.

The data driver DDR receives image data DATA from the controller CTR, and supplies data voltages to the plurality of data lines DL, thereby driving the plurality of data lines DL.

The data driver DDR is also referred to as a source driver.

The data driver DDR can exchange various signals with the controller CTR through various interfaces.

The gate driver GDR supplies a scan signal sequentially to the plurality of gate lines GL, thereby sequentially driving the plurality of gate lines GL.

The gate driver GDR is also referred to as a scan driver.

The gate driver GDR supplies a scan signal of an on voltage or an off voltage sequentially to the plurality of gate lines GL under the control of the controller CTR.

When a specific gate line GL is open by the gate driver GDR, the data driver DDR converts image data DATA received from the controller CTR into analog type data voltages, and supplies the data voltages to the plurality of data lines DL.

The data driver DDR can be located on one side (e.g., the upper side or the lower side) of the display panel PLN, but is not limited thereto.

For example, the data driver DDR can be located on both sides (e.g., the upper side and the lower side) of the display panel PLN depending on a driving method, a display panel design method, etc.

The gate driver GDR can be located on one side (e.g., the left side or the right side) of the display panel PLN, but is not limited thereto.

For example, the gate driver GDR can be located on both sides (e.g., the left side and the right side) of the display panel PLN depending on a driving method, a display panel design method, etc.

The data driver DDR can be implemented to include at least one source driver integrated circuit (SDIC).

Each source driver integrated circuit (SDIC) can include a shift register, a latch circuit, a digital-to-analog converter (DAC) and an output buffer.

Also, the data driver DDR can further include at least one analog-to-digital converter (ADC).

Each source driver integrated circuit (SDIC) can be connected to a bonding pad of the display panel PLN in a tape automated bonding (TAB) type or a chip-on-glass (COG) type.

Alternatively, each source driver integrated circuit (SDIC) can be disposed directly on the display panel PLN.

Also, each source driver integrated circuit (SDIC) can be disposed by being integrated in the display panel PLN.

In addition, each source driver integrated circuit (SDIC) can be implemented in a chip-on-film (COF) type.

In this situation, each source driver integrated circuit (SDIC) can be mounted on a circuit film.

Each source driver integrated circuit (SDIC) mounted on the circuit film can be electrically connected to the data lines DL in the display panel PLN through the circuit film.

The gate driver GDR can include a plurality of gate driving circuits GDC.

The plurality of gate driving circuits GDC can correspond to the plurality of gate lines GL, respectively.

Each gate driving circuit GDC can include a shift register and a level shifter.

Each gate driving circuit GDC can be connected to a bonding pad of the display panel PLN in a tape automated bonding (TAB) type or a chip-on-glass (COG) type.

In addition, each gate driving circuit GDC can be implemented in a chip-on-film (COF) type.

In this situation, each gate driving circuit GDC can be mounted on a circuit film.

Each gate driving circuit GDC mounted on the circuit film can be electrically connected to the gate lines GL in the display panel PLN through the circuit film.

In addition, each gate driving circuit GDC can be implemented in a gate-in-panel (GIP) type, and can be embedded in the display panel PLN.

Accordingly, each gate driving circuit GDC can be formed directly in the display panel PLN.

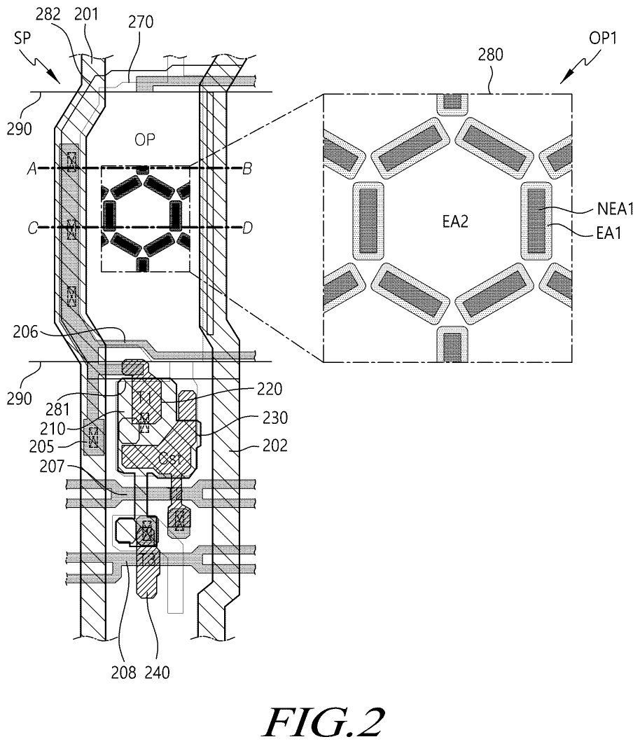

FIG. 2 is a plan view illustrating a partial area of a subpixel disposed in the active area of a display panel according to embodiments of the present disclosure.

Referring to FIG. 2, at least one subpixel SP of the display device 100 according to the embodiments of the present disclosure can include an area which overlaps with a bank 290 and an area which overlaps with an opening OP of the bank 290.

The area which overlaps with the bank 290 can include a non-light emitting area, and in the non-light emitting area, a plurality of signal lines 201, 202, 203, 204, 205, 206, 207 and 208, a light shield 210 and a plurality of active layers 220, 230 and 240 can be disposed.

The plurality of signal lines can include first to eighth signal lines 201, 202, 203, 204, 205, 206, 207 and 208, and the plurality of active layers can include first to third active layers 220, 230 and 240.

Referring to FIG. 2, in the area that overlaps with the bank 290, a plurality of transistors T1, T2 and T3 and a storage capacitor Cst for driving a light emitting element disposed in the subpixel SP can be disposed.

In the opening OP of the bank 290, the light emitting element including a first electrode, an organic layer and a second electrode can be disposed.

Color filters 281 and 282 can be disposed in the area which overlaps with the opening OP, but the present disclosure is not limited thereto.

For example, the color filters 281 and 282 can be disposed in only some subpixels SP among the plurality of subpixels SP included in the display device 100, or the color filters 281 and 282 can be disposed in none of the subpixels SP included in the display device 100.

When the color filters 281 and 282 are disposed in the subpixel SP, as shown in FIG. 2, the color filters 281 and 282 can overlap with a plurality of light emitting areas EA1 and EA2.

Referring to FIG. 2, in the display device 100 according to the embodiments of the present disclosure, the plurality of light emitting areas EA1 and EA2 can be disposed in the area which overlaps with the opening OP of the bank 290.

For example, in one opening OP provided in one subpixel SP, a plurality of first light emitting areas EA1 and a plurality of second light emitting areas EA2 can be disposed, and a plurality of first non-light emitting areas NEA1 can be disposed.

Referring to FIG. 2, in the area which overlaps with the opening OP of the bank 290, the plurality of first non-light emitting areas NEA1 can be disposed to be spaced apart from each other.

Each first non-light emitting area NEA1 can be surrounded by the first light emitting area EA1.

Each of the plurality of first light emitting areas EA1 can have a structure in which at least a partial outer portion thereof is surrounded by the second light emitting area EA2.

The number of first light emitting areas EA1 can be equal to the number of first non-light emitting areas NEA1.

Referring to FIG. 2, the plurality of first non-light emitting areas NEA1 disposed in at least one subpixel SP can be arranged in a hexagonal shape with some areas open, but are not limited thereto. The first non-light emitting areas NEA1 of the display device 100 according to the embodiments of the present disclosure can be arranged in various shapes.

Referring to FIG. 2, the plurality of first non-light emitting areas NEA1, the plurality of first light emitting areas EA1 and the second light emitting area EA2 which overlap with one opening OP in at least one subpixel SP can overlap with the color filters 281 and 282.

The plurality of first light emitting areas EA1 and the one second light emitting area EA2 included in one subpixel SP can emit the same color.

The luminance of the plurality of first light emitting areas EA1 and the luminance of the second light emitting areas EA2 included in one subpixel SP can be the same or substantially same.

However, the optical characteristics of the display device 100 according to the embodiments of the present disclosure are not limited thereto, and the luminance of the plurality of first light emitting areas EA1 included in one subpixel SP can be lower than the luminance of the one second light emitting area EA2.

The second light emitting area EA2 can be disposed to surround at least a portion of each of the plurality of first light emitting areas EA1.

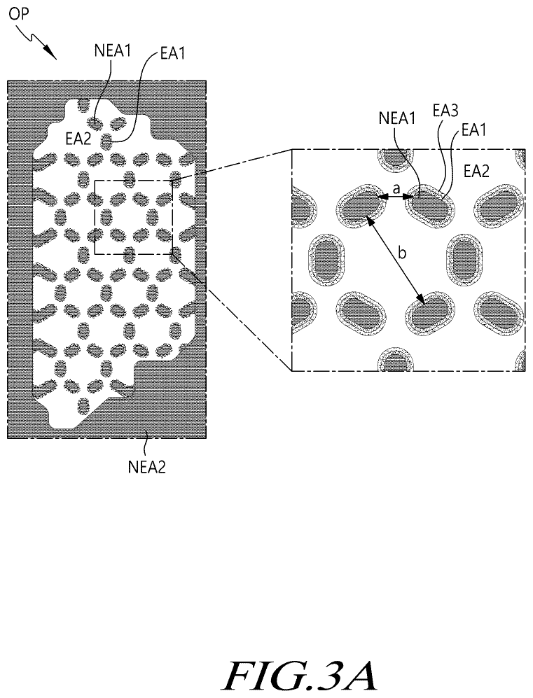

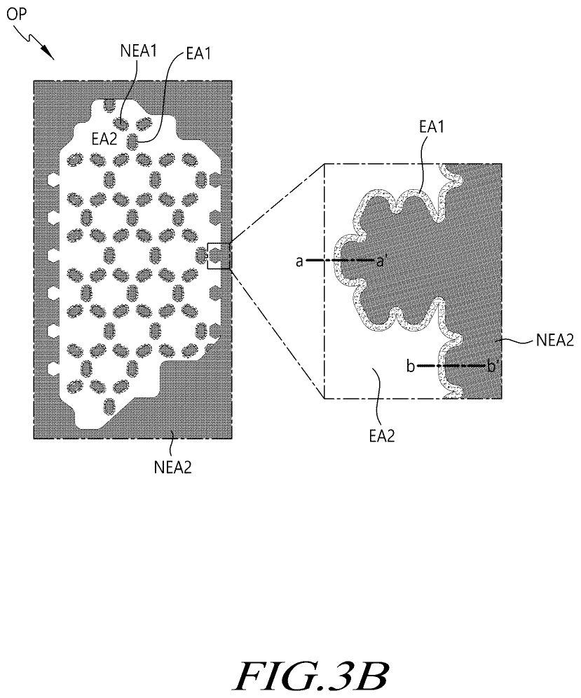

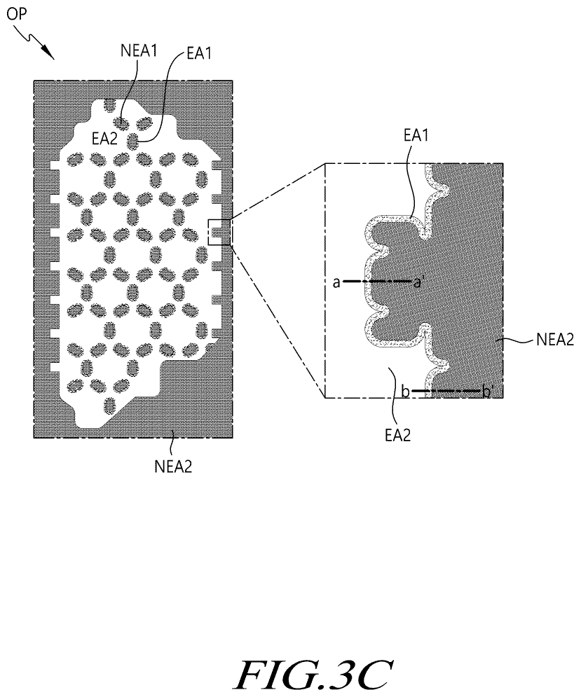

FIGS. 3A to 3C are diagrams illustrating the light emitting area of a display device according to embodiments of the present disclosure.

Referring to FIGS. 3A to 3C, in the display device 100 according to the embodiments of the present disclosure, a plurality of light emitting areas EA1 and EA2 and a plurality of first non-light emitting areas NEA1 can be provided in one subpixel.

For example, the plurality of light emitting areas EA1 and EA2 can be disposed in one opening OP of a bank, and as shown in FIG. 3A, the plurality of first non-light emitting areas NEA1 can be disposed in one opening OP of the bank.

Referring to FIG. 3A, the plurality of first non-light emitting areas NEA1 disposed in one opening OP of the bank can be arranged in a structure in which hexagonal shapes with open corners (e.g., hexagonal shapes with the first non-light emitting area NEA1 not disposed at each of corners) are connected to each other. Also, the plurality of first non-light emitting areas NEA1 disposed in one opening OP of the bank can be arranged in repeating patterns, such as repeating ring shapes, perforated ring shapes or overlapping ring shapes, but embodiments are not limited thereto.

For example, six first non-light emitting areas NEA1 can form a hexagonal shape with open corners, and a structure in which a plurality of hexagonal shapes composed of a plurality of first non-light emitting areas NEA1 are arranged can be provided.

One hexagonal shape can be arranged to share at least one first non-light emitting area NEA1 with another adjacent hexagonal shape.

Referring to FIG. 3A, the plurality of first non-light emitting areas NEA1 disposed in one opening OP of the bank can be disposed to be spaced apart from each other.

One first non-light emitting area NEA1 and another adjacent first non-light emitting area NEA1 can be spaced apart by a first distance a.

The first distance a can mean the shortest straight line distance between one point of one first non-light emitting area NEA1 and one point of another first non-light emitting area NEA1.

For example, when the first non-light emitting area NEA1 has a shape (e.g., a polygonal shape) which has at least one corner or one side in a plan view, one corner or one side of another adjacent first non-light emitting area NEA1 can be disposed at a position spaced apart by the first distance a which is the shortest straight line distance, based on one corner or one side of one first non-light emitting area NEA1.

In addition, one side of one first non-light emitting area NEA1 disposed in one opening OP of the bank can be disposed to face one side of another first non-light emitting area NEA1 in a plan view.

One side of one first non-light emitting area NEA1 can be spaced apart by a second distance b from one side of another first non-light emitting area NEA1 which faces the one first non-light emitting area NEA1. In other words, opposite sides of the first non-light emitting areas NEA1 or opposite facing first non-light emitting areas NEA1 can be spaced apart from each other by the second distance b.

Referring to FIG. 3A, when two first non-light emitting areas NEA1 disposed farthest away from each other in a plan view among six first non-light emitting areas NEA1 forming one hexagonal shape are selected, the second distance b can mean the shortest straight line distance between one side (e.g., a first side) of one first non-light emitting area NEA1 of the two first non-light emitting areas NEA1 and one side (e.g., a side facing the first side) of the other first non-light emitting area NEA1.

Referring to FIG. 3A, the first distance a can be shorter than the second distance b (e.g., a<b).

For example, when each first non-light emitting area NEA1 has a shape (e.g., a polygonal shape, a circular shape, an elliptical shape, a polygonal shape with rounded corners, etc.) having a certain area in a plan view and a hexagonal structure is formed as six first non-light emitting areas NEA1 are arranged, the first distance a can be 5 μm to 15 μm (e.g., 10 μm), and the second distance b can be 10 μm to 20 μm (e.g., 15 μm).

However, the ranges of the first distance a and the second distance b are not limited thereto, and various distances can be selected depending on the shape of a pattern, the size of the opening OP of the bank, etc.

Each of the plurality of first light emitting areas EA1 disposed in one subpixel can be an area where light emitted from a light emitting layer is emitted to the outside of a substrate by a reflective electrode disposed in the first non-light emitting area NEA1.

In this way, by adjusting the first and second distances a and b of the first non-light emitting areas NEA1, the efficiency of light generated from the plurality of first light emitting areas EA1 can be improved due to the first non-light emitting areas NEA1 while reducing or minimizing the area of each first non-light emitting area NEA1 disposed in the opening OP of the bank.

In the above, a situation where the plurality of first non-light emitting areas NEA1, the plurality of first light emitting areas EA1 and the plurality of second light emitting area EA2 are disposed in the opening OP of the bank was described with reference to FIG. 3A.

Hereinafter, a situation where a plurality of first non-light emitting areas NEA1, a plurality of first light emitting areas EA1 and a plurality of second light emitting area EA2 are disposed at the boundary between the second light emitting area EA2 and a second non-light emitting area NEA2 will be described with reference to FIGS. 3B and 3C.

Description for the first non-light emitting areas NEA1, the first light emitting areas EA1 and the second light emitting areas EA2 in FIGS. 3B and 3C are substantially the same as description for the first non-light emitting areas NEA1, the first light emitting areas EA1 and the second light emitting areas EA2 in FIG. 3A.

Referring to FIGS. 3B and 3C, a plurality of first non-light emitting areas NEA1, a plurality of first light emitting areas EA1 and a plurality of second light emitting areas EA2 can be disposed at the boundary between the second light emitting area EA2 and the second non-light emitting area NEA2, and the boundary between the second light emitting area EA2 and the second non-light emitting area NEA2 can have concave and convex shapes.

Specifically, the boundary between the second light emitting area EA2 and the second non-light emitting area NEA2 can have a polygonal shape, and preferably, can be a hexagonal shape or a quadrangular shape.

However, the concave and convex of the boundary between the second light emitting area EA2 and the second non-light emitting area NEA2 are not necessarily limited to a polygonal shape, and can have various shapes such as a circular shape or an elliptical shape. For example, the boundary between the second light emitting area EA2 and the second non-light emitting area NEA2 can have ruffled shaped edges, a wavy shape or a curvy shape (e.g., a type of leaf pattern or clover pattern).

In addition, the boundary between the second light emitting area EA2 and the second non-light emitting area NEA2 is not necessarily limited to concave and convex shapes, and may not have concave and convex shapes.

Referring to FIGS. 3B and 3C, the concave and convex shapes of the boundary between the second light emitting area EA2 and the second non-light emitting area NEA2 can have a first shape and a second shape.

Specifically, the first shape can be formed in a direction in which the second light emitting area EA2 exists, on one side of the opening OP of the bank, and the second shape can be formed in a direction in which the second non-light emitting area NEA2 exists, on the other side of the opening OP of the bank.

Unlike the first shape, in the second shape, the first light emitting area EA1 may not exist along the direction in which the second non-light emitting area NEA2 exists.

In FIG. 3B, an example in which the first shape and the second shape are hexagonal shapes is illustrated, and an enlarged view of the first shape is shown.

In FIG. 3C, an example in which the first shape and the second shape are quadrangular shapes is illustrated, and an enlarged view of the first shape is shown.

It can be desirable that the first shape and the second shape are the same or substantially same shape. However, the first shape and the second shape are not necessarily limited to the same or substantially same shape, and can be different shapes.

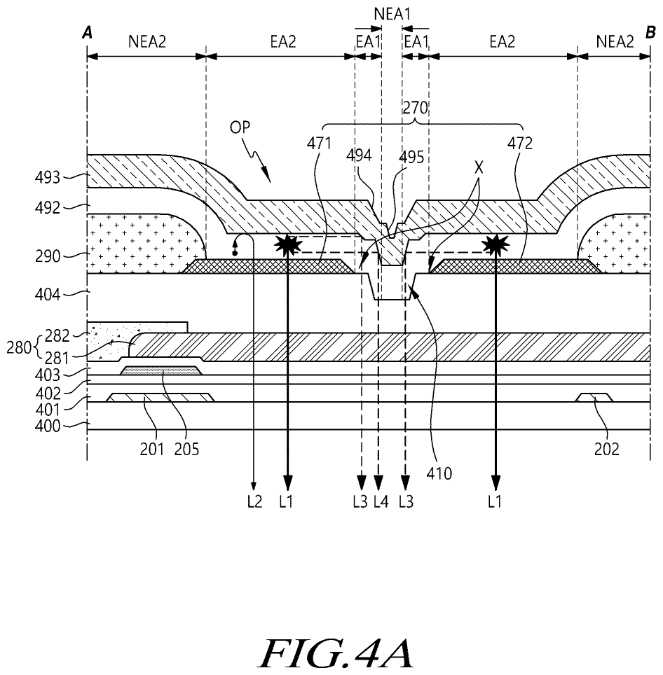

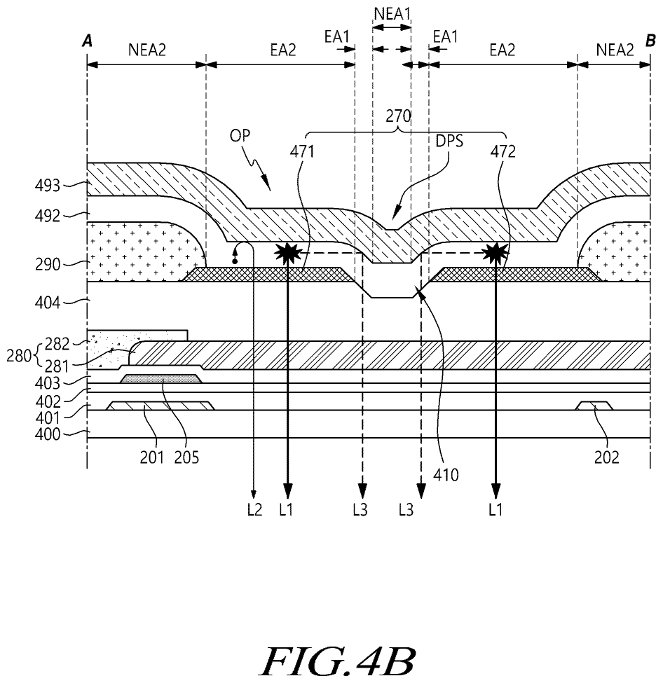

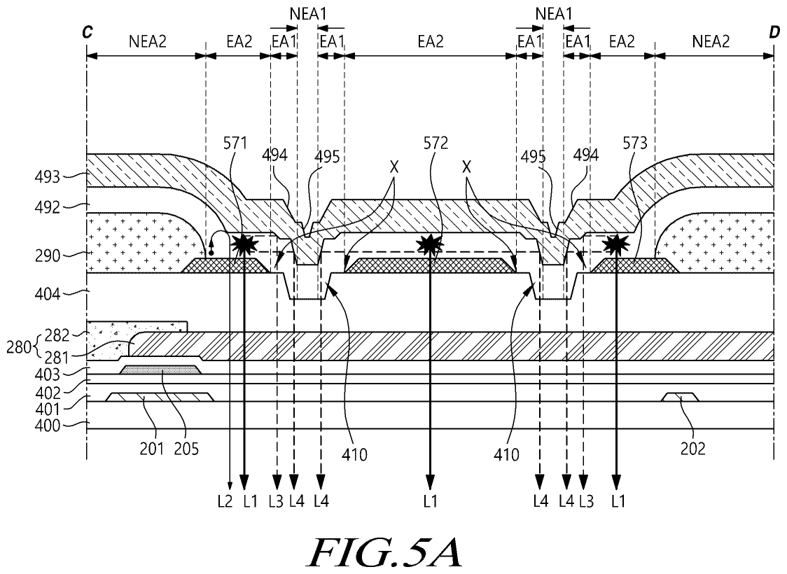

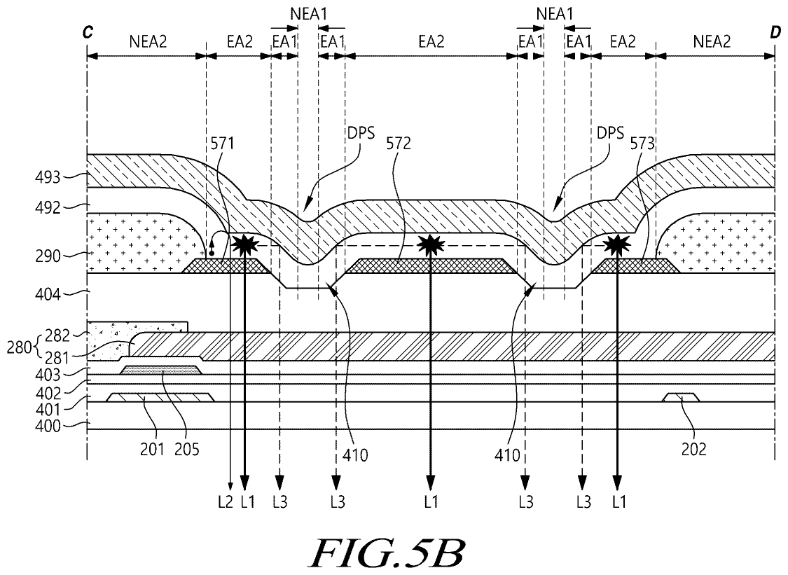

In succession, with reference to FIGS. 4A, 4B, 5A and 5B, the structure of the display device according to the embodiments of the present disclosure will be described below in detail.

FIGS. 4A and 4B are cross-sectional views taken along the line A-B of FIG. 2, and FIGS. 5A and 5B are cross-sectional views taken along the line C-D of FIG. 2.

Referring to FIGS. 4A, 4B, 5A and 5B, a first signal line 201 and a second signal line 202 can be disposed on a substrate 400.

A first insulating layer 401 can be disposed on the first and second signal lines 201 and 202.

The first insulating layer 401 can be a buffer layer, and can have a single-layer or multi-layer structure.

A second insulating layer 402 can be disposed on the first insulating layer 401.

The second insulating layer 402 can be a gate insulating layer.

The first and second insulating layers 401 and 402 can include an inorganic insulating material such as silicon oxide (SiOx), silicon nitride (SiNx) or silicon oxynitride (SiON), but the embodiments of the present disclosure are not limited thereto.

A fifth signal line 205 can be disposed on the second insulating layer 402.

Each of the first signal line 201, the second signal line 202 and the fifth signal line 205 can include a conductive material.

For example, each of the signal lines 201, 202 and 205 can include metal such as aluminum (Al), gold (Au), silver (Ag), copper (Cu), tungsten (W), molybdenum (Mo), chromium (Cr), tantalum (Ta) and titanium (Ti) or an alloy thereof, but the embodiments of the present disclosure are not limited thereto.

A third signal line 203 and a fourth signal line 204 shown in FIG. 2 can include the same or substantially same material as the first and second signal lines 201 and 202, but the embodiments of the present disclosure are not limited thereto.

A third insulating layer 403 can be disposed on the fifth signal line 205.

The color filter 280 can be disposed on the third insulating layer 403.

The color filter 280 can include a first color filter 281 and a second color filter 282, and the first color filter 281 and the second color filter 282 can be color filters of different colors.

For example, the first color filter 281 can be a red color filter, and the second color filter 282 can be a green color filter.

In FIGS. 4A, 4B, 5A and 5B, a structure in which the color filter 280 includes the first color filter 281 and the second color filter 282 is illustrated, but the structure of the display device 100 according to the embodiments of the present disclosure is not limited thereto. The color filter 280 disposed on the third insulating layer 403 can further include at least one color filter except the first and second color filters 281 and 282.

The additionally included color filter can be a color filter (e.g., a blue color filter) of a different color from the first and second color filters 281 and 282 or a color filter of the same color.

Referring to FIGS. 4A, 4B, 5A and 5B, one end of the first color filter 281 can overlap with one end of the second color filter 282.

An area where portions of the first and second color filters 281 and 282 overlap with can serve as a black matrix (e.g., two or more different color filters can overlap with each other to block light).

A fourth insulating layer 404 can be disposed on the color filter 280.

The fourth insulating layer 404 can include an organic insulating material, but the embodiments of the present disclosure are not limited thereto.

A plurality of anode electrodes 270 can be disposed on the fourth insulating layer 404.

The anode electrode 270 can include a transparent conductive material.

For example, the anode electrode 270 can include at least one of ITO (indium tin oxide), IZO (indium zinc oxide) and IGZO (indium gallium zinc oxide), but the material of the anode electrode 270 according to the embodiments of the present disclosure is not limited thereto. Any composition including a material with high light transmittance and high conductivity is sufficient.

Referring to FIGS. 4A, 4B, 5A and 5B, in one subpixel, the plurality of anode electrodes 270 can be disposed on the fourth insulating layer 404 to be spaced apart from each other.

Referring to FIGS. 4A, 4B, 5A and 5B, in the area between at least two anode electrodes 270, at least one recess portion 410 can be defined in the fourth insulating layer 404.

For example, referring to FIGS. 4A and 4B, a first anode electrode 471 and a second anode electrode 472 can be disposed on the fourth insulating layer 404 to be spaced apart from each other.

The at least one recess portion 410 can be provided in the fourth insulating layer 404 to correspond to the area between the first anode electrode 471 and the second anode electrode 472.

Each of the first anode electrode 471 and the second anode electrode 472 can be disposed around the recess portion 410 of the fourth insulating layer 404 to expose a portion of the upper surface of the fourth insulating layer 404.

In other words, in the area between the first anode electrode 471 and the second anode electrode 472, a portion of the upper surface of the fourth insulating layer 404 where the recess portion 410 is not disposed may not overlap the first and second anode electrodes 471 and 472. For example, the first and second anode electrodes 471 and 472 can be separated from each other by the recess portion 410 therebetween.

Referring to FIGS. 5A and 5B, at least one recess portion 410 can be provided between a first anode electrode 571 and a second anode electrode 572 which are disposed on the fourth insulating layer 404, and at least one recess portion 410 can be provided between the second anode electrode 572 and a third anode electrode 573.

Referring to FIGS. 5A and 5B, in the area between the first anode electrode 571 and the second anode electrode 572, a portion of the upper surface of the fourth insulating layer 404 where the recess portion 410 is not disposed may not overlap with the first and second anode electrodes 571 and 572. For example, the first and second anode electrodes 571 and 572 can be separated from each other by the recess portion 410 therebetween.

In addition, in the area between the second anode electrode 572 and the third anode electrode 573, a portion of the upper surface of the fourth insulating layer 404 where the recess portion 410 is not disposed may not overlap with the second and third anode electrodes 572 and 573. Similarly, the second and third anode electrodes 572 and 573 can be separated from each other by the recess portion 410 therebetween.

Referring to FIGS. 4A, 4B, 5A and 5B, the bank 290 can be disposed on portions of the upper surfaces of the anode electrodes 270 which are disposed on the fourth insulating layer 404.

The bank 290 can have at least one opening OP in one subpixel.

The bank 290 can be made of a transparent organic material or a black-colored organic material.

For example, as shown in FIGS. 4A and 4B, the bank 290 can be disposed on a portion of the upper surface of the first anode electrode 471 and a portion of the upper surface of the second anode electrode 472. For example, the bank 290 can overlap with an edge of an anode electrode.

The opening OP of the bank 290 can be disposed on the other portion of the upper surface of the first anode electrode 471 and the other portion of the upper surface of the second anode electrode 472.

As shown in FIGS. 5A and 5B, the bank 290 can be disposed on a portion of the upper surface of the first anode electrode 571 and a portion of the upper surface of the third anode electrode 573, and may not be disposed on the upper surface of the second anode electrode 572.

The opening OP of the bank 290 can overlap with the other portion of the upper surface of the first anode electrode 571, the other portion of the upper surface of the third anode electrode 573 and the entire upper surface of the second anode electrode 572.

Referring to FIGS. 4A, 4B, 5A and 5B, the opening OP of the bank 290 can overlap with the recess portion 410 of the fourth insulating layer 404 which is disposed between the anode electrodes 270.

Referring to FIGS. 4A, 4B, 5A and 5B, a light emitting layer 492 can be disposed over the substrate 400 over which the anode electrodes 270 and the bank 290 are disposed, and a cathode electrode 493 can be disposed on the light emitting layer 492.

FIGS. 4A, 4B, 5A and 5B illustrate a structure in which each of the light emitting layer 492 and the cathode electrode 493 is a single layer, but the embodiments of the present disclosure are not limited thereto. At least one of the light emitting layer 492 and the cathode electrode 493 can have a multilayer structure.

Referring to FIGS. 4A, 4B, 5A and 5B, the light emitting layer 492 and the cathode electrode 493 can be disposed on the bank 290 and the opening OP of the bank 290.

The cathode electrode 493 can include a conductive material that can reflect light.

For example, the cathode electrode 493 can include metal such as aluminum (Al), magnesium (Mg), gold (Au), silver (Ag), copper (Cu), tungsten (W), molybdenum (Mo), chromium (Cr), tantalum (Ta) and titanium (Ti) or an alloy thereof, but the embodiments of the present disclosure are not limited thereto.

Referring to FIGS. 4A, 4B, 5A and 5B, the light emitting layer 492 and the cathode electrode 493 can be disposed on the recess portion 410 of the fourth insulating layer 404 which overlaps with the opening OP of the bank 290.

The light emitting layer 492 and the cathode electrode 493 can be disposed even in an area X (hereinafter, referred to as an exposed area) where the anode electrodes 270 expose the portion of the fourth insulating layer 404 around the recess portion 410 of the fourth insulating layer 404. For example, the light emitting layer 492 and the cathode electrode 493 can extend continuously across adjacent anode electrodes and the recess portion 410 between the adjacent anode electrodes.

In the exposed area X and the recess portion 410, the light emitting layer 492 can contact the upper surface of the fourth insulating layer 404.

Referring to FIGS. 4A, 4B, 5A and 5B, the light emitting layer 492 and the cathode electrode 493 can be formed along the morphologies of the anode electrode 270 and the fourth insulating layer 404 in the opening OP of the bank 290.

Referring to FIGS. 4A and 5A, the light emitting layer 492 and the cathode electrode 493 can have steps 494 and 495 in the opening OP of the bank 290. Also, steps 494 and 495 can also be referred to as stepped portions or inclined portions.

Specifically, each of the light emitting layer 492 and the cathode electrode 493 can have a first step 494 at the boundary between the exposed area X (e.g., an area where the anode electrodes 270 do not overlap with the upper surface of the fourth insulating layer 404 except the recess portion 410) and the anode electrodes 270, and can have a second step 495 at the boundary between the exposed area X and the recess portion 410. In an embodiment, the first step 494 of the cathode electrode 493 can overlap with an inclined side surface of the recess portion 410 in the insulating layer 404, and the second step 495 of the cathode electrode 493 can overlap with a flat bottom surface of the recess portion 410 in the insulating layer 404.

Accordingly, the location of the cathode electrode 493 disposed on the exposed area X and the recess portion 410 can be lower than the location of the cathode electrode 493 disposed on the anode electrodes 270.

The location of the cathode electrode 493 can be determined through the shortest straight line distance from the upper surface of the substrate 400 to the lower surface of the cathode electrode 493. For example, portions of the light emitting layer 492 and the cathode electrode 493 can sink down into recess portion 410. Also, the recess portion 410 can be referred to a groove or depression, but embodiments are not limited thereto.

Specifically, referring to FIGS. 4A and 5A, the shortest straight line distance between the lower surface of the cathode electrode 493 disposed on the anode electrodes 270 and the upper surface of the substrate 400 can be longer than the shortest straight line distance between the lower surface of the cathode electrode 493 disposed on the exposed area X and the recess portion 410 and the upper surface of the substrate 400.

Accordingly, the location of the lower surface of the cathode electrode 493 disposed on the anode electrodes 270 can be higher than the location of the lower surface of the cathode electrode 493 disposed on the exposed area X and the recess portion 410.

For another example, referring to FIGS. 4B and 5B, the light emitting layer 492 and the cathode electrode 493 can include a round-shaped depression DPS in the opening OP of the bank 290.

In order to form the round-shaped depression DPS, it is preferable that the end of the recess portion 410 and the ends of the anode electrodes 270 contact each other, but the embodiments of the present disclosure are not necessarily limited thereto.

The fact that the end of the recess portion 410 and the ends of the anode electrodes 270 contact each other can be interpreted to mean that the exposed area X described in FIGS. 4A and 5A does not exist.

However, the embodiments of the present disclosure are not limited to the absence of the exposed area X, and even though the exposed area X exists, the depression DPS can have a round shape.

Referring to FIGS. 4A, 4B, 5A and 5B, one subpixel can include a first light emitting area EA1, a second light emitting area EA2, a first non-light emitting area NEA1 and a second non-light emitting area NEA2.

The first light emitting area EA1, the second light emitting area EA2 and the first non-light emitting area NEA1 can be defined where the opening OP of the bank 290 is provided.

The second non-light emitting area NEA2 can be an area where the bank 290 is disposed.

Referring to FIGS. 4A, 4B, 5A and 5B, the first non-light emitting area NEA1 can overlap with the recess portion 410 of the fourth insulating layer 404.

Specifically, the first non-light emitting area NEA1 can correspond to an area where, in a cross-sectional view, the straight line distance between the substrate 400 and the lower surface of the cathode electrode 493 in the opening OP of the bank 290 is shortest (e.g., the area overlapping with a center portion or flat bottom portion of the recess portion 410).

The recess portion 410 of the fourth insulating layer 404 can be composed of a flat portion and an inclined surface surrounding the outline of the flat portion, and the first non-light emitting area NEA1 can be an area corresponding to at least a portion of the flat portion of the recess portion 410.

The first light emitting area EA1 can be an area corresponding to the exposed area X and the inclined surface of the recess portion 410 of the fourth insulating layer 404. The first light emitting area EA1 can surround the periphery of the first non-light emitting area NEA1.

The second light emitting area EA2 can be an area corresponding to an area where the anode electrodes 270 are disposed. The second light emitting area EA2 can surround the periphery of the first light emitting area EA1.

The second non-light emitting area NEA2 can surround the periphery of the second light emitting area EA2.

In the second light emitting area EA2, a portion of light generated from the light emitting layer 492 can be emitted from the light emitting layer 492 through the anode electrodes 270 to the outside of the substrate 400 (first light L1 of FIGS. 4A, 4B, 5A and 5B).

Another portion of light generated from the light emitting layer 492 can be emitted from the light emitting layer 492 toward the cathode electrode 493, but can be reflected by the cathode electrode 493 including a reflective conductive material and can be emitted to the outside of the substrate 400 through the anode electrodes 270 (second light L2 of FIGS. 4A, 4B, 5A and 5B).

Still another portion of light generated from the light emitting layer 492 located between the anode electrodes 270 and the cathode electrode 493 can be emitted in a direction intersecting a direction in which the buffer layer 401 is stacked on the substrate 400, can be reflected from the cathode electrode 493 disposed in the first light emitting area EA1 to be changed in its path toward the substrate 400, and can be finally emitted to the outside of the substrate 400 (e.g., third light L3 and fourth light L4 of FIGS. 4A, 4B, 5A and 5B). In other words, some of the light generated from the light emitting layer 492 (e.g., horizontal light that otherwise may remain internally reflected or blocked) can be reflected out of the display device by a portion of the cathode electrode 493 that sinks down into recess portion 410 and this reflected light can pass between adjacent anodes and out of the display device without being obstructed by the transparent anodes. Thus, more light can be emitted out of the subpixel with less power.

Specifically, referring to FIGS. 4A and 5A, still another portion of light generated from the light emitting layer 492 located between the anode electrodes 270 and the cathode electrode 493 can reach the area of the first step 494 or the second step 495 of the cathode electrode 493, and can be reflected in the area of the first step 494 or the second step 495 to be changed in its path to be emitted to the outside of the substrate 400.

As such, due to the fact that the fourth insulating layer 404 includes at least one recess portion 410 in one subpixel and the exposed area X where the anode electrodes 270 are disposed to expose the upper surface of the fourth insulating layer 404 is provided, the cathode electrode 493 can include the area of at least one first step 494 and the area of at least one second step 495 which can help reflect more light out of the subpixel.

Since light generated from the light emitting layer 492 can be emitted to the outside without loss through the areas of the first and second steps 494 and 495 (e.g., without any loss due to having to pass through an anode electrode), light efficiency can be increased.

In other words, light emitted from the first light emitting area EA1 can be light emitted as a portion of light emitted by the anode electrodes 270, the light emitting layer 492 and the cathode electrode 493 located in the second light emitting area EA2 is reflected.

Referring to FIGS. 3A to 3C, one first light emitting area EA1 can be disposed to surround the periphery of one first non-light emitting area NEA1.

Because the recess portion 410 of the fourth insulating layer 404 can be formed simultaneously in a process of forming a contact hole for electrically connecting the anode electrodes 270 disposed on the fourth insulating layer 404 and a transistor, a separate process for light extraction may not be added.

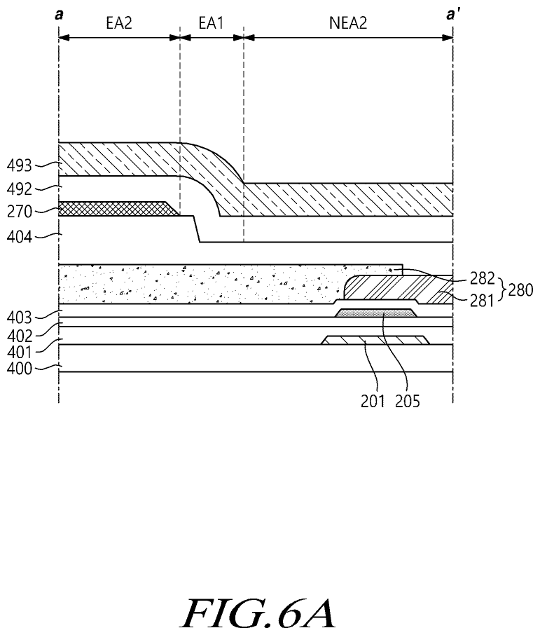

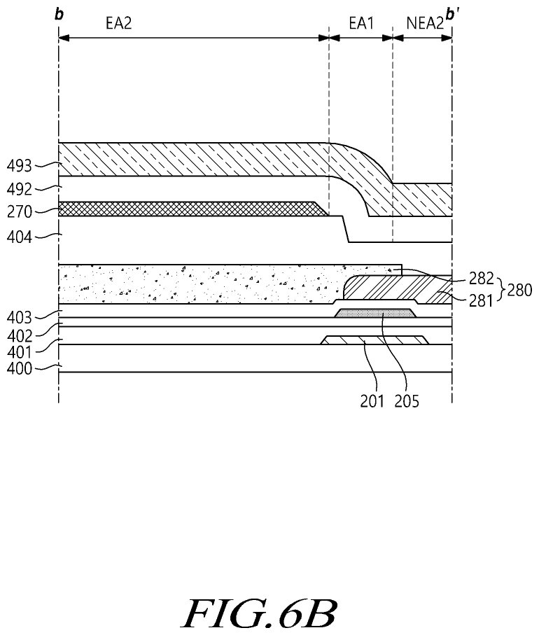

FIGS. 6A and 6B are cross-sectional views taken along the lines a-a′ and b-b′, respectively, of FIG. 3B (or FIG. 3C).

A substrate 400, first to fourth insulating layers 401, 402, 403 and 404, color filters 281 and 282, signal lines 201 and 205, anode electrodes 270, a light emitting layer 492, a cathode electrode 493, light emitting areas EA1 and EA2 and a non-light emitting area NEA of FIG. 6A are substantially the same as the substrate 400, the first to fourth insulating layers 401, 402, 403 and 404, the color filters 281 and 282, the signal lines 201 and 205, the anode electrodes 270, the light emitting layer 492, the cathode electrode 493, the light emitting areas EA1 and EA2 and the non-light emitting area NEA described above with reference to FIGS. 4A to 5B.

Referring to FIGS. 6A and 6B, the light emitting layer 492 and the cathode electrode 493 can include a round-shaped step in the first light emitting area EA1.

The round-shaped step is formed due to the step of the fourth insulating layer 404 in the first light emitting area EA1.

Referring to FIG. 6A, the round-shaped step in the first light emitting area EA1 located at the boundary between the second light emitting area EA2 and the second non-light emitting area NEA2 may not overlap with the signal lines 201 and 205.

However, the embodiments of the present disclosure are not limited thereto. Referring to FIG. 6B, the round-shaped step in the first emitting area EA1 located at the boundary between the second emitting area EA2 and the second non-light emitting area NEA2 can overlap with the signal lines 201 and 205. Whether the round-shaped step overlaps with the signal lines 201 and 205 can vary depending on the location of the boundary between the second light emitting area EA2 and the second non-light emitting area NEA2.

Referring to FIGS. 6A and 6B, in the second light emitting area EA2 adjacent to the boundary between the second light emitting area EA2 and the second non-light emitting area NEA2, an area where a bank is not disposed on the anode electrodes 270 can exist.

Namely, the bank may not be disposed on one side and the other side of the boundary of an opening.

In the second light emitting area EA2 adjacent to the boundary between the second light emitting area EA2 and the second non-light emitting area NEA2, an area where a bank is not disposed on the anode electrodes 270 may not exist.

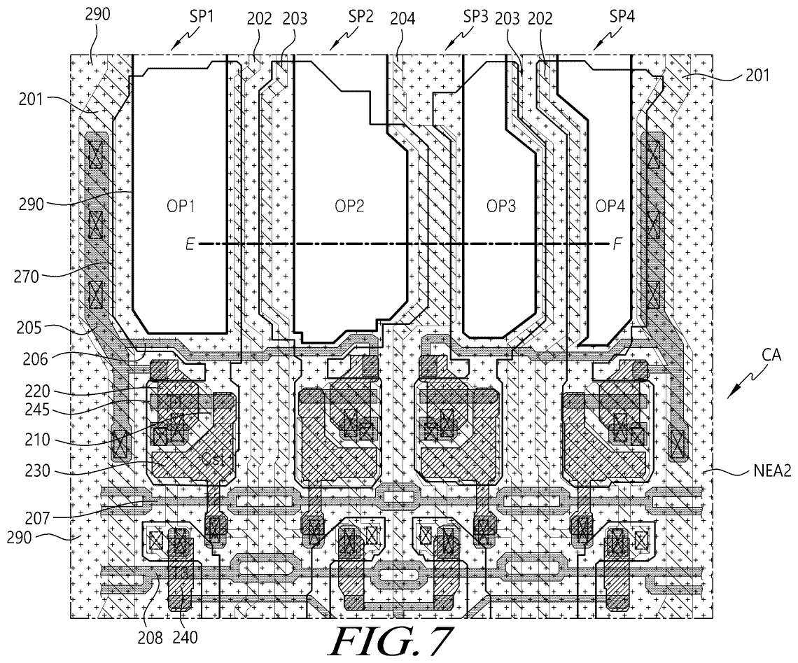

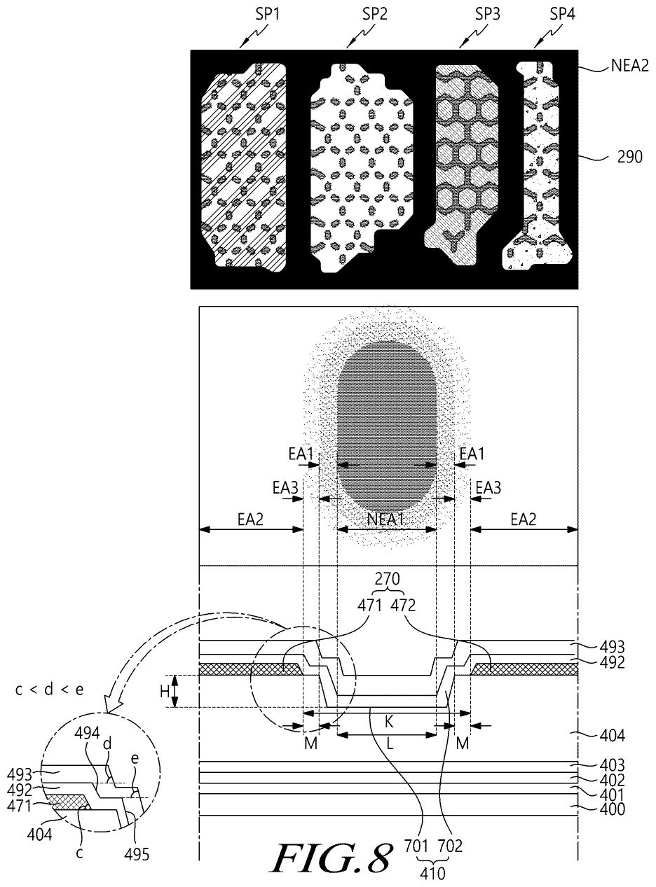

Next, with reference to FIGS. 7 and 8, the planar structure of a display device according to embodiments of the present disclosure will be described below.

FIG. 7 is a diagram illustrating a planar structure of four subpixels in a display device according to embodiments of the present disclosure.

FIG. 8 is a diagram illustrating a cross-sectional structure showing opening areas of a bank of four subpixels and a plurality of light emitting areas and a non-light emitting area in a display device according to embodiments of the present disclosure.

Referring to FIGS. 7 and 8, the display device according to the embodiments of the present disclosure can include a first subpixel SP1, a second subpixel SP2, a third subpixel SP3 and a fourth subpixel SP4.

The first to fourth subpixels SP1, SP2, SP3 and SP4 can include light emitting areas which emit light of different colors.

For example, the first subpixel SP1 can include a light emitting area which emits red light, the second subpixel SP2 can include a light emitting area which emits white light, the third subpixel SP3 can include a light emitting area which emits blue light, and the fourth subpixel SP4 can include a light emitting area which emits green light.

As shown in FIG. 8, each of the light emitting areas included in the subpixels SP1, SP2, SP3 and SP4 can include a first non-light emitting area NEA1, a first light emitting area EA1 which surrounds the first non-light emitting area NEA1, a third light emitting area EA3 which surrounds the first light emitting area EA1, and a second light emitting area EA2 which surrounds the third light emitting area EA3. The second light emitting area EA2 can be surrounded by a second non-light emitting area NEA2.

Comparing the structures of the non-light emitting areas and the light emitting areas of FIG. 8 with the structures of FIGS. 3A, 3B, 3C to 5A and 5B, a difference is that the third light emitting area EA3 is additionally disposed between the first light emitting area EA1 and the second light emitting area EA2 (e.g., corresponding to an area between an edge of an anode electrode and an upper edge of the recess portion 410).

The first light emitting area EA1 can be an area corresponding to the inclined surface of the recess portion 410, and the third light emitting area EA3 can be an area corresponding to an area of the upper surface of the fourth insulating layer 404 extending from the inclined surface, which does not overlap with the anode electrodes 270.

Each of the first to fourth subpixels SP1, SP2, SP3 and SP4 can include a circuit area CA for driving a light emitting element disposed in each of the first to fourth subpixels SP1, SP2, SP3 and SP4.

Referring to FIG. 7, each of the first to fourth subpixels SP1, SP2, SP3 and SP4 can include a plurality of transistors T1, T2 and T3 and a storage capacitor Cst which are disposed in the circuit area CA.

For example, the circuit area CA of each of the first to fourth subpixels SP1, SP2, SP3 and SP4 can include a first transistor T1, a second transistor T2, a third transistor T3 and the storage capacitor Cst.

Referring to FIG. 7, the circuit area CA of each of the first to fourth subpixels SP1, SP2, SP3 and SP4 can overlap with the bank 290.

In other words, the bank 290 can overlap with the first transistor T1, the second transistor T2, the third transistor T3 and the storage capacitor Cst.

Specifically, the bank 290 can overlap with a gate electrode 245 and a first active layer 220 included in the first transistor T1, can overlap with a second active layer 230 included in the second transistor T2 and a third active layer 240 included in the third transistor T3, and can overlap with a light shield 210 which is one of the electrodes of the storage capacitor Cst.

Referring to FIG. 7, the bank 290 can overlap with a plurality of signal lines 201, 202, 203, 204, 205 and 206 which are required to drive the light emitting element.

Some of a plurality of signal lines 201, 202, 203, 204, 205, 206, 207 and 208 can serve as any one of the source electrode, the drain electrode and the gate electrode of each of the transistors T1, T2 and T3.

Referring to FIGS. 7 and 8, an area where the bank 290 is disposed can be substantially the same as the second non-light emitting area NEA2 of an active area A/A.

Being substantially the same in the present disclosure can mean the same degree in consideration of a minute difference due to an error in a process.

Referring to FIG. 7, the bank 290 can include a first opening OP1, a second opening OP2, a third opening OP3 and a fourth opening OP4.

The first opening OP1 can be included in the first subpixel SP1, the second opening OP2 can be included in the second subpixel SP2, the third opening OP3 can be included in the third subpixel SP3, and the fourth opening OP4 can be included in the fourth subpixel SP4.

Referring to FIGS. 7 and 8, each of the first to fourth openings OP1, OP2, OP3 and OP4 can include a plurality of light emitting areas EA1, EA2 and EA3 and a plurality of first non-light emitting areas NEA1.

Specifically, the structures of the plurality of light emitting areas EA1, EA2 and EA3 and the plurality of first non-light emitting areas NEA1 which overlap with the second opening OP2 of the second subpixel SP2 shown in FIG. 8 will be described below as an example.

In the following description, the structure of an area corresponding to the second opening OP2 of the second subpixel SP2 will be described by way of example, but, except for a configuration in which color filters are additionally disposed on the third insulating layer 403 in the first opening OP1 of the first subpixel SP1, the third opening OP3 of the third subpixel SP3 and the fourth opening OP4 of the fourth subpixel SP4, the remaining configuration can be the same or substantially same.

Referring to FIG. 8, the second opening OP2 of the second subpixel SP2 can include the first non-light emitting area NEA1, the first light emitting area EA1 which surrounds the first non-light emitting area NEA1, the third light emitting area EA3 which surrounds the first light emitting area EA1, and the second light emitting area EA2 which surrounds the third light emitting area EA3.

Referring to FIG. 8, the first non-light emitting area NEA1 can correspond to an area corresponding to a flat portion 701 of the recess portion 410 of the fourth insulating layer 404 (e.g., the middle, lowest portion of 410).

The first light emitting area EA1 can correspond to an area corresponding to an inclined surface 702 of the recess portion 410 provided in the fourth insulating layer 404.

The third light emitting area EA3 can correspond to an area in which the anode electrodes 270 are not disposed on the fourth insulating layer 404 and which does not overlap with the recess portion 410 (e.g., area between an edge of an anode electrode and an upper edge of the recess portion 410).

The second light emitting area EA2 can be an area which includes an area where the anode electrodes 270 are disposed but in which the anode electrodes 270 do not overlap with the bank 290.

The luminance of the third light emitting area EA3 can be lower than the luminance of the first light emitting area EA1 and the luminance of the second light emitting area EA2. However, the luminance characteristics of the display device according to the embodiments of the present disclosure are not limited thereto, and can be adjusted depending on the structure of the recess portion 410 of the fourth insulating layer 404, the locations of the anode electrodes 270 and the recess portion 410 and the taper angle of the anode electrodes 270.

For example, a width L of the flat portion 701 (e.g., bottom portion) of the recess portion 410 of the fourth insulating layer 404 can be 0.5 μm to 3.5 μm (e.g., 2.0 μm).

The width L of the flat portion 701 can be a shortest length in a direction intersecting a direction in which the first insulating layer 401 is stacked on the substrate 400.

A height H of the recess portion 410 of the fourth insulating layer 404 can be 0.4 μm to 1 μm (e.g., 0.7 μm).

Referring to FIG. 8, a gap K between the first anode electrode 471 and the second anode electrode 472 can be 3.7 μm to 5.5 μm.

The gap K can mean a shortest straight line distance between one end of the first anode electrode 471 and one end of the second anode electrode 472 in the direction perpendicular to the direction in which the first insulating layer 401 is stacked on the substrate 400.

Referring to FIG. 8, in the remaining area except for the recess portion 410 of the fourth insulating layer 404 in the second opening OP2, a width M of an area in which the anode electrodes 270 do not overlap with the fourth insulating layer 404 can be 0.5 μm to 0.6 μm (e.g., 0.55 μm).

Referring to FIG. 8, a first angle c of the first anode electrode 471 can be 25° to 30° (e.g., the taper angle of the edge of the first anode electrode 471).

Also, the angle of the second anode electrode 472 can be the same as or similar to the first angle c of the first anode electrode 471.

The cathode electrode 493 disposed over the first and second anode electrodes 471 and 472 can include a second angle d and a third angle e. Specifically, referring to FIG. 8, the cathode electrode 493 can form the second angle d in an area provided with the first step 494, and can form the third angle e in an area provided with the second step 495.

The second angle d can be 30° to 50° (e.g., 40°), and the third angle e can be 50° to 70° (e.g., 60°).

In FIG. 8, the first angle c can mean an angle that is formed by the inclined surface of one end of the first anode electrode 471 with respect to the surface of the substrate 400, and the second angle d and third angle e can mean angles that are formed by inclined surfaces due to the first and second steps 494 and 495 of the cathode electrode 493 with respect to the surface of the substrate 400.

Referring to FIG. 8, the third angle e can be larger than the first and second angles c and d, and the second angle d can be larger than the first angle c (e.g., e>d>c).

Referring to FIG. 8, the second angle d of the cathode electrode 493 can be formed by one end of the anode electrode 470 where the first angle c of the anode electrode 470 is defined, and the third angle e of the cathode electrode 493 can be formed due to the boundary of the recess portion 410 of the fourth insulating layer 404.

Through this structure, the cathode electrode 493 can be provided with the first step 494 and the second step 495 which form the second angle d and the third angle e, and due to the first step 494 and the second step 495, light generated from the light emitting layer 492 can be emitted to the outside of the substrate 400 by being reflected by the cathode electrode 493.

Accordingly, at least one subpixel can have a structure which includes a plurality of light emitting areas.

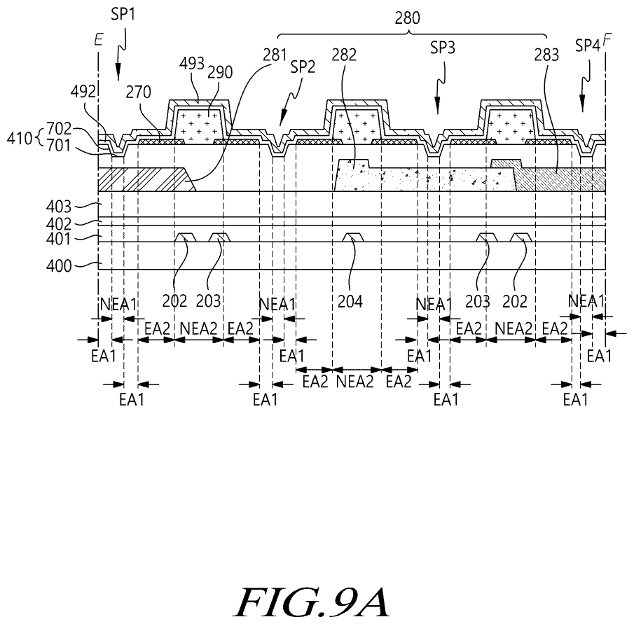

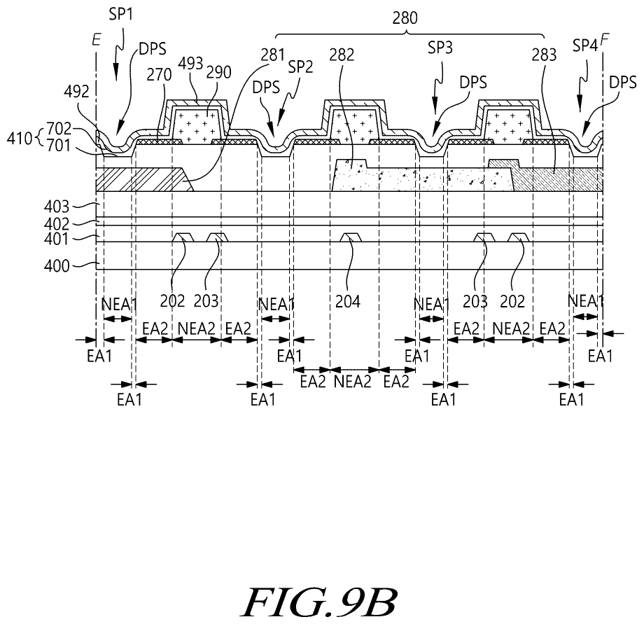

FIGS. 9A and 9B are cross-sectional views taken along the line E-F of FIG. 7 according to embodiments of the present disclosure.

Referring to FIGS. 9A and 9B, each of the first subpixel SP1, the second subpixel SP2, the third subpixel SP3 and the fourth subpixel SP4 can include a plurality of first light emitting areas EA1 and a second light emitting area EA2.

Specifically, referring to FIGS. 9A and 9B, in each of the first to fourth subpixels SP1, SP2, SP3 and SP4, at least one recess portion 410 provided in the fourth insulating layer 404 can be disposed in an area corresponding to the opening of the bank 290.

In each of the first to fourth subpixels SP1, SP2, SP3 and SP4, an area corresponding to the flat portion 701 of the recess portion 410 of the fourth insulating layer 404 can be the first non-light emitting area NEA1.

At least one first non-light emitting area NEA1 can be disposed in each of the first to fourth subpixels SP1, SP2, SP3 and SP4, and can be disposed in the bank 290.

Referring to FIGS. 9A and 9B, in each of the first subpixel SP1, the third subpixel SP3 and the fourth subpixel SP4, the first non-light emitting area NEA1 can overlap with the color filter 280.

In each of the first to fourth subpixels SP1, SP2, SP3 and SP4, an area corresponding to the inclined surface 702 of the recess portion 410 of the fourth insulating layer 404 can be included in the first light emitting area EA1.

In addition, in the opening of the bank 290 of each of the first to fourth subpixels SP1, SP2, SP3 and SP4, an area in which the anode electrodes 270 do not overlap with the fourth insulating layer 404 in the remaining area except for the recess portion 410 can also be included in the first light emitting area EA1.

Referring to FIGS. 9A and 9B, in the opening of the bank 290 of each of the first to fourth subpixels SP1, SP2, SP3 and SP4, an area in which the fourth insulating layer 404 and the anode electrodes 270 overlap with each other can be the second light emitting area EA2.

In the first to fourth subpixels SP1, SP2, SP3 and SP4, an area which overlaps with the bank 290 can be the second non-light emitting area NEA2.

Referring to FIGS. 9A and 9B, the plurality of signal lines 202, 203 and 204 can be disposed to overlap with the bank 290.

Each of the plurality of signal lines 202, 203 and 204 may not overlap with the first and second light emitting areas EA1 and EA2.

Accordingly, light emitted from the first and second light emitting areas EA1 and EA2 of the first to fourth subpixels SP1, SP2, SP3 and SP4 can be reduced or prevented from being lost or obstructed by the plurality of signal lines 202, 203 and 204.

Referring to FIGS. 9A and 9B, as the first to fourth insulating layers 401, 402, 403 and 404 and the bank 290 are disposed between the plurality of signal lines 202, 203 and 204 and the cathode electrode 493, the distance between the plurality of signal lines 202, 203 and 204 and the cathode electrode 493 can increase.

Accordingly, the parasitic capacitance between the plurality of signal lines 202, 203 and 204 and the cathode electrode 493 can decrease as well. Thus, noise can be reduced and brightness can be improved.

The distance between the plurality of signal lines 202, 203 and 204 and the cathode electrode 493 means the shortest straight line length between the upper surface of each of the plurality of signal lines 202, 203 and 204 and the lower surface of the cathode electrode 493.

The plurality of first non-light emitting areas NEA1 disposed in each of the subpixels SP1, SP2, SP3 and SP4 can be arranged in a hexagonal shape with partial areas (e.g., corner portions) open in a plan view, as shown in FIG. 2.

Here, open can also mean that the first non-light emitting area NEA1 is not disposed.

However, the first non-light emitting areas of each subpixel according to the embodiments of the present disclosure are not limited to being arranged in a hexagonal shape with partial areas open in a plan view, and can be arranged in various shapes.

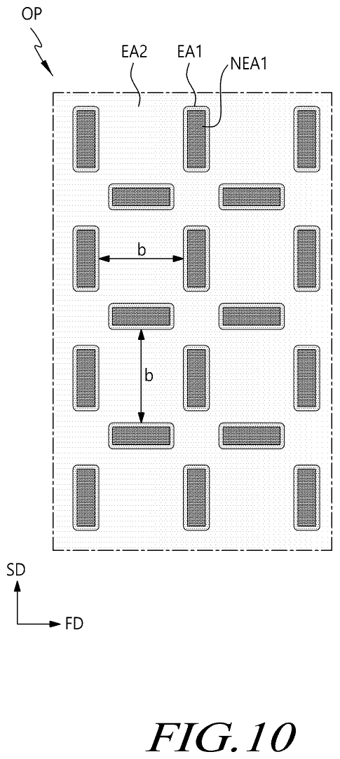

This will be described below with reference to FIGS. 10 to 12.

FIGS. 10 to 12 are diagrams each illustrating a planar structure of an area corresponding to the opening of a bank in at least one subpixel disposed in the active area of a display panel according to embodiments of the present disclosure.

Referring to FIGS. 10 to 12, in an area corresponding to the opening OP of the bank 290 in the display panel according to the embodiments of the present disclosure, a plurality of first non-light emitting areas NEA1, a plurality of first light emitting areas EA1 and a second light emitting area EA2 can be disposed.

Referring to FIGS. 10 to 12, the plurality of first non-light emitting areas NEA1 can be disposed to be spaced apart from each other.

The first light emitting area EA1 can be disposed to surround each first non-light emitting area NEA1.

The second light emitting area EA2 can be disposed to surround the plurality of first light emitting areas EA1.

FIGS. 10 to 12 illustrate a structure in which the second light emitting area EA2 surrounds the first light emitting area EA1. However, the structure of the display panel according to the embodiments of the present disclosure is not limited thereto, and as shown in FIG. 8, the third light emitting area EA3 can be additionally disposed between the first light emitting area EA1 and the second light emitting area EA2.

Referring to FIG. 10, some of the plurality of first non-light emitting areas NEA1 can be arranged so that their long sides are located in a first direction, and the remaining some of the plurality of first non-light emitting areas NEA1 can be arranged so that their long sides are located in a second direction.

Referring to FIG. 10, a plurality of first non-light emitting areas NEA1 whose long sides are located in the first direction and a plurality of first non-light emitting areas NEA1 whose long sides are located in the second direction may not overlap each other in a plan view.

For example, at least four first non-light emitting areas NEA1 can be arranged in a quadrangular shape with open corners.

Referring to FIG. 10, the plurality of first non-light emitting areas NEA1 and the plurality of first light emitting areas EA1 which surround the first non-light emitting areas NEA1 can be arranged in a quadrangular shape with open corners in a plan view. For example, the plurality of first non-light emitting areas NEA1 can have rectangular shapes and be arranged in a series of columns intersecting a series of rows.

In at least one subpixel, a plurality of quadrangular shapes with open corners which are formed by the plurality of first non-light emitting areas NEA1 can be arranged in the first direction, and can be arranged in the second direction as well.

Referring to FIG. 10, the first non-light emitting area NEA1 and the first light emitting area EA1 which surrounds the first non-light emitting area NEA1 can be disposed.

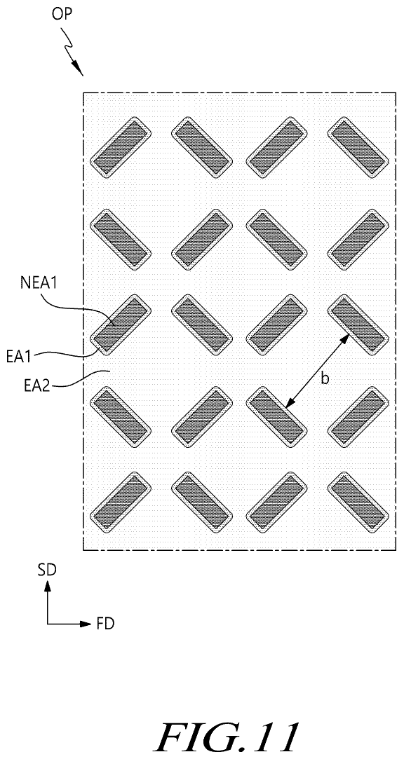

However, the embodiments of the present disclosure are not limited thereto, and as shown in FIG. 11, at least four first non-light emitting areas NEA1 and the first light emitting areas EA1 surrounding them can be arranged in a rhombus shape with open corners. For example, the plurality of first non-light emitting areas NEA1 can have rectangular shapes and be arranged in a repeating “X” pattern.

In at least one subpixel, a plurality of rhombus shapes with open corners which are formed by a plurality of first non-light emitting areas NEA1 can be arranged in the first direction, and can be arranged in the second direction as well.

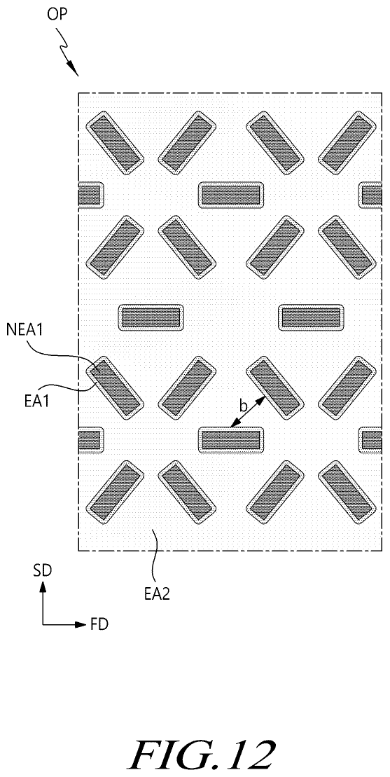

Referring to FIG. 12, at least two first non-light emitting areas NEA1 and the first light emitting areas EA1 surrounding them can be arranged in a direction the same as or similar to the first direction in a plan view.

Referring to FIG. 12, at least four first non-light emitting areas NEA1 and the first light emitting areas EA1 surrounding them can be disposed in an area between the first direction and the second direction to be spaced apart from each other in a plan view.

Referring to FIG. 12, in an area corresponding to the opening of the bank disposed in one subpixel, when connecting the outer edges of six first non-light emitting areas NEA1 and the first light emitting areas EA1 surrounding them, a hexagonal shape can be formed. For example, the plurality of first non-light emitting areas NEA1 can be arranged in a star pattern or a spoke pattern around a common center point.

Referring to FIGS. 10 to 12, the distance (hereinafter referred to as the second distance b) between one first non-light emitting area NEA1 whose long side is located in the first direction and another first non-light emitting area NEA1 which is located closest and whose long side is located in the first direction can be 10 μm to 20 μm (e.g., 15 μm).

In addition, the distance (the second distance b) between one first non-light emitting area NEA1 whose long side is located in the second direction and another first non-light emitting area NEA1 which is located closest and whose long side is located in the second direction can also be 10 μm to 20 μm (e.g., 15 μm).

In this way, as the second distance b is in the range of 10 μm to 20 μm (e.g., 15 μm), it is possible to achieve the effect of realizing high resolution and improving or maximizing light efficiency of the display panel according to the embodiments of the present disclosure.

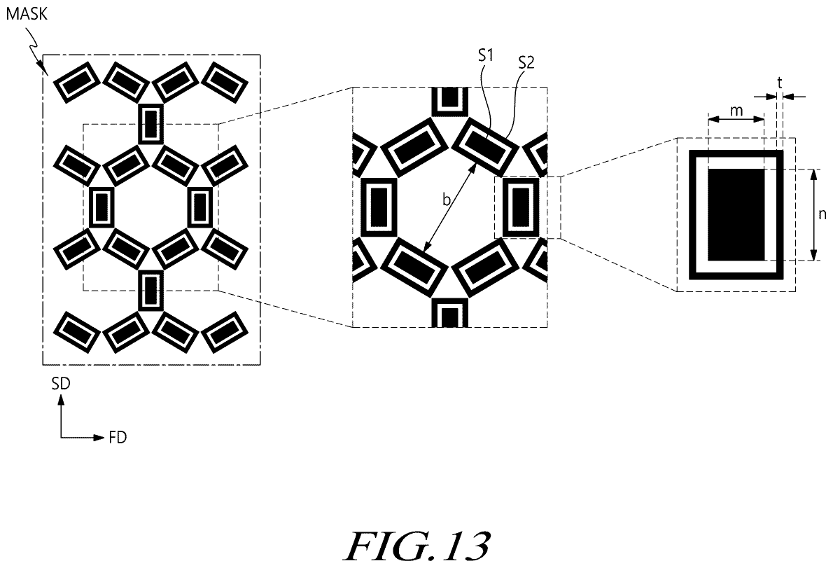

FIG. 13 is a plan view illustrating the shape of a mask MASK used to manufacture the planar structure of an area corresponding to the opening of a bank in at least one subpixel disposed in the active area of a display panel according to embodiments of the present disclosure.

Referring to FIG. 13, by using a mask MASK which has a first slit S1 and a second slit S2, it is possible to manufacture the planar structure of an area corresponding to the opening OP of the bank in at least one subpixel disposed in the active area of the display panel according to the embodiments of the present disclosure.

In FIG. 13, a situation where the first slit S1 is a rectangular slit with a short side of m and a long side of n and the second slit S2 surrounding the first slit S1 has a thickness of t will be described as an example. The shapes of the first slit S1 and the second slit S2 are not limited thereto, and can be modified in various ways depending on the shape of the planar structure.

One side of a second slit S2 can be disposed to face one side of another second slit S2 when viewed on a plane defined by a first direction FD and a second direction SD perpendicular to the first direction FD.

One side of one second slit S2 can be spaced apart from one side of another second slit S2 facing the one second slit S2 by the second distance b.

In order to adjust the taper angle of the anode electrode 270 described above, the short side m and the long side n of the first slit S1 of the mask MASK and the thickness t of the second slit S2 can be adjusted.

Specifically, in order to decrease the taper angle of the anode electrode 270, the short side m of the first slit S1 can be 1 μm to 5 μm, the long side n can be 1 μm to 10 μm, and the thickness t of the second slit S2 can be 0.5 μm to 3 μm.

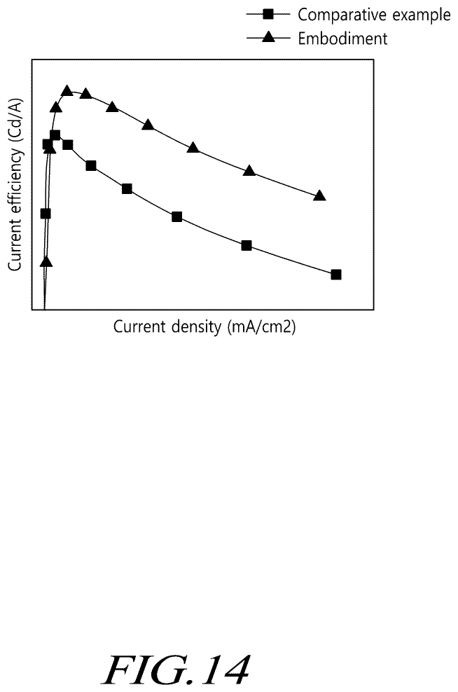

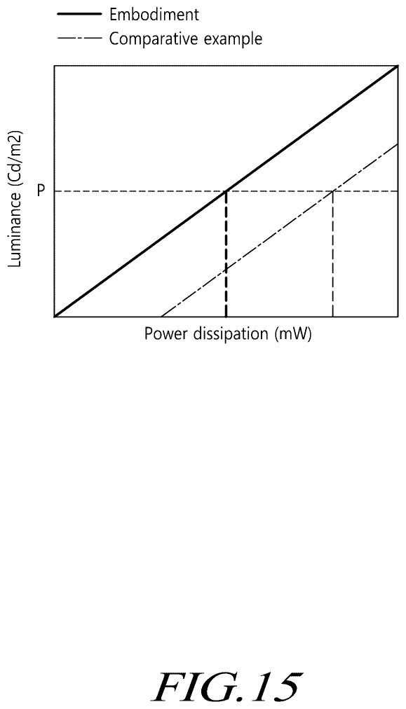

FIGS. 14 and 15 are graphs comparing the characteristics of light emitted from one subpixel of a display panel according to embodiments of the present disclosure and the characteristics of light emitted from one subpixel of a display panel according to a comparative example.

Specifically, FIG. 14 is a graph comparing the light efficiencies of the display panel according to the embodiments of the present disclosure and the display panel according to the comparative example, and FIG. 15 is a graph comparing power consumption of the display panel according to the embodiments of the present disclosure and the display panel according to the comparative example.

The structure of the display panel according to the embodiments of FIGS. 14 and 15 can be the structure shown in FIG. 8.

The structure of the display panel according to the comparative example of FIGS. 14 and 15, as the structure of a general display panel, can be a structure in which one subpixel is composed of one light emitting area (an area corresponding to the opening of a bank) and a non-light emitting area surrounding the light emitting area.

Referring to FIG. 14, it can be seen that at the same current density, the display panel according to the embodiments of the present disclosure has higher light efficiency than the display panel according to the comparative example.

Referring to FIG. 15, it can be seen that at the same power consumption, the display panel according to the embodiments of the present disclosure has a higher luminance value than the display panel according to the comparative example.

In other words, it can be seen that in order to achieve a specific luminance value P, the power consumption of the display panel according to the embodiments of the present disclosure is lower than the power consumption of the display panel according to the comparative example. Thus, the display panel according to the embodiments of the present disclosure can use less power and provide greater brightness.

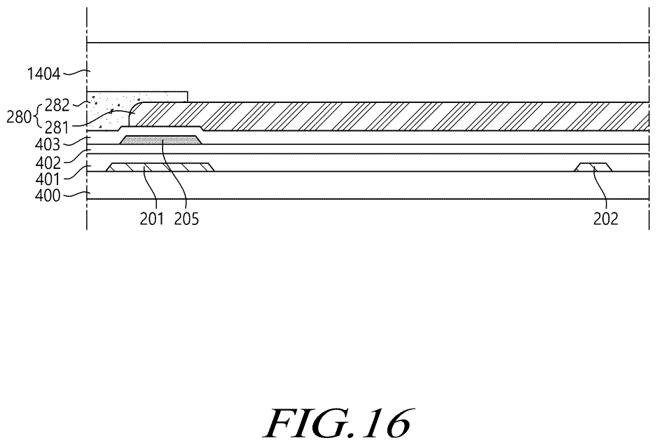

FIGS. 16 to 20 are diagrams schematically showing the manufacturing process of a display panel according to embodiments of the present disclosure.

Referring to FIG. 16, first and second signal lines 201 and 202 can be disposed on a substrate 400, and first and second insulating layers 401 and 402 can be sequentially disposed on the substrate 400 on which the first and second signal lines 201 and 202 are disposed.

A fifth signal line 205 and a third insulating layer 403 can be sequentially disposed on the second insulating layer 402.

Thereafter, a color filter 280 can be disposed on the third insulating layer 403.

Referring to FIG. 16, a fourth insulating layer material 1404 can be disposed on the substrate 400 over which the color filter 280 is disposed.

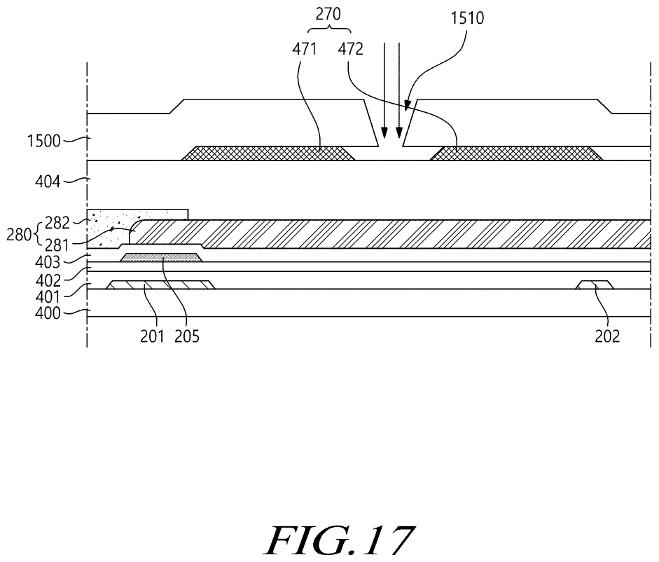

Referring to FIG. 17, a plurality of anode electrodes 270 including first and second anode electrodes 471 and 472 can be disposed on the fourth insulating layer material 1404.

The plurality of anode electrodes 270 can be disposed to be spaced apart from each other, and can be disposed to expose a portion of the upper surface of the fourth insulating layer material 1404.

Referring to FIG. 17, a photoresist 1500 can be disposed on the plurality of anode electrodes 270.

The photoresist 1500 can include at least one hole 1510 in one subpixel.

The hole 1510 of the photoresist 1500 can be formed to overlap with an area where the plurality of anode electrodes 270 are not disposed.

For example, referring to FIG. 17, the hole 1510 of the photoresist 1500 can be formed to overlap with the area between the first anode electrode 471 and the second anode electrode 472 (e.g., between two adjacent anode electrodes).

In addition, the hole 1510 of the photoresist 1500 can be disposed to overlap with a portion of the upper surface of the fourth insulating layer material 1404 which is exposed by the first anode electrode 471 and the second anode electrode 472.

Thereafter, a portion of the fourth insulating layer material 1404 can be patterned using the photoresist 1500 including the hole 1510 as a mask.

Specifically, referring to FIG. 17, when a dry etching process is performed in a state in which the photoresist 1500 including the hole 1510 is disposed, the fourth insulating layer material 1404 can be patterned in an area where the photoresist 1500 is not disposed.

After patterning the fourth insulating layer material 1404, the photoresist 1500 can be removed.

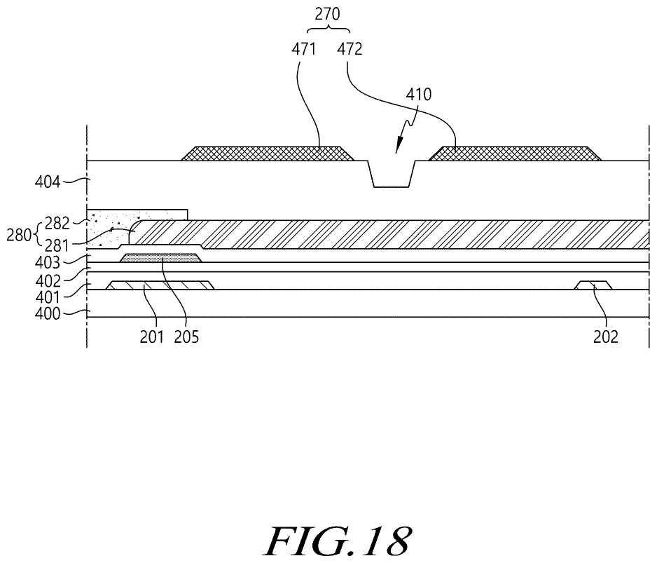

Accordingly, as shown in FIG. 18, after the dry etching process of the fourth insulating layer material 1404, a fourth insulating layer 404 which is formed with a recess portion 410 can be formed.

Specifically, referring to FIGS. 17 and 18, due to the fact that the hole 1510 of the photoresist 1500 is disposed between the first anode electrode 471 and the second anode electrode 472 to overlap with the portion of the upper surface of the fourth insulating layer material 1404 exposed by the plurality of anode electrodes 270, the fourth insulating layer material 1404 can be removed in only a partial area between the first anode electrode 471 and the second anode electrode 472. For example, a depression or groove can be formed in the fourth insulating layer 404 between the first anode electrode 471 and the second anode electrode 472.

Accordingly, the recess portion 410 formed in the fourth insulating layer 404 can be disposed to be spaced apart from the first anode electrode 471 and the second anode electrode 472.

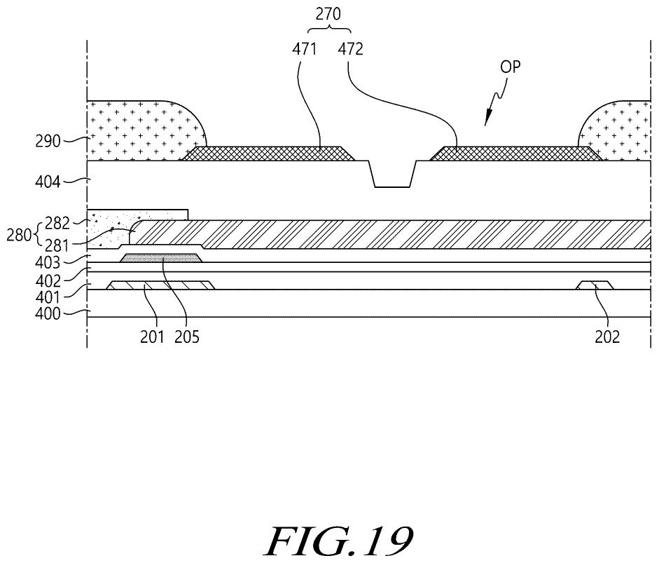

Thereafter, as shown in FIG. 19, a bank 290 including an opening OP can be disposed over the substrate 400.

A portion of the opening OP of the bank 290 can overlap with the entire recess portion 410 of the fourth insulating layer 404.

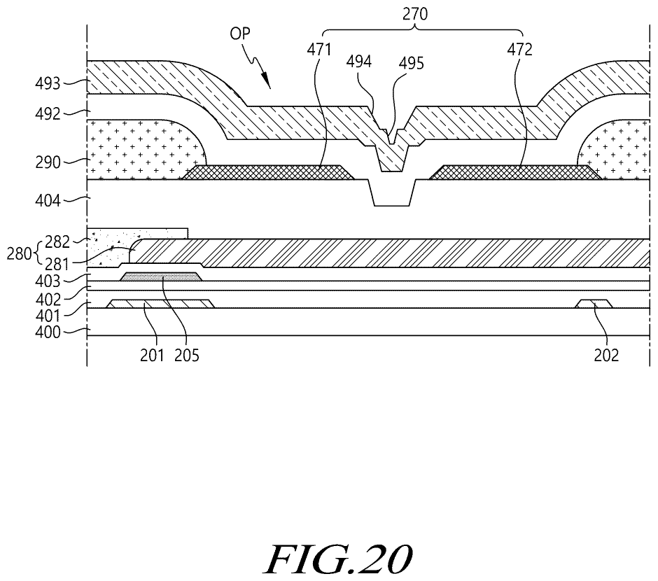

Thereafter, as shown in FIG. 20, a light emitting layer 492 and a cathode electrode 493 can be sequentially disposed on the substrate 400 over which the bank 290 is disposed. For example, a portion of the cathode electrode 493 can sink down into or be positioned lower over recess portion 410 and some of the light generated from the light emitting layer 492 can be reflected out of the display device. For example, this reflected light can pass between adjacent anodes and out of the display device without being obstructed by the transparent anodes. Thus, more light can be emitted out of the subpixel with less power.

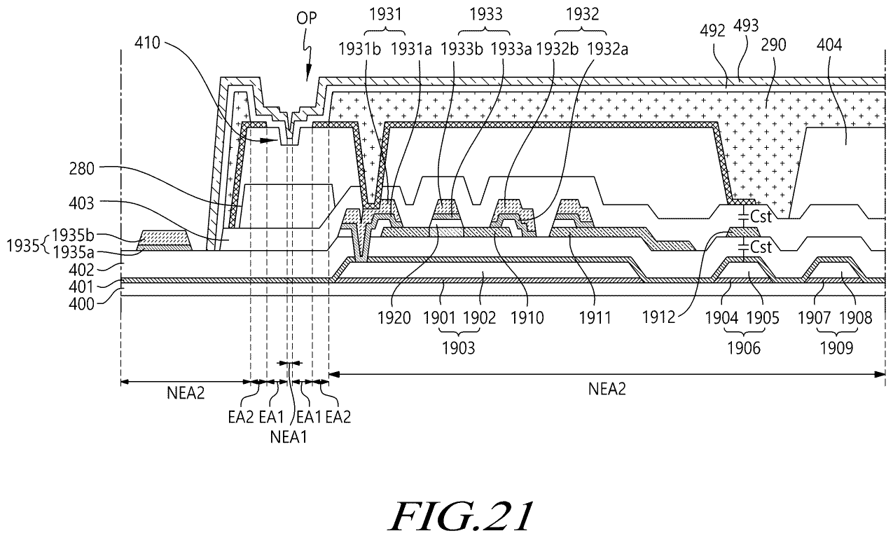

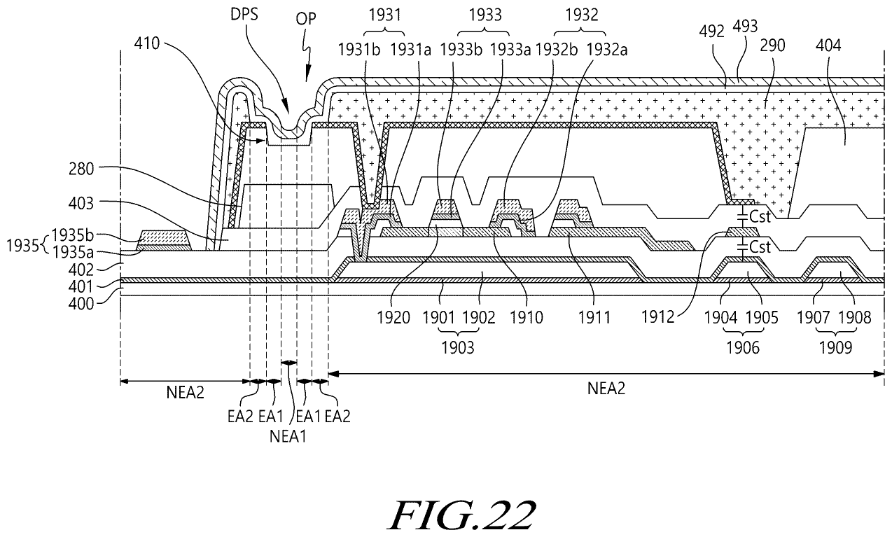

The structure of the display panel according to the embodiments of the present disclosure will be further described below with reference to FIGS. 21 and 22.

FIGS. 21 and 22 are diagrams each showing the cross-sectional structure of a display panel according to embodiments of the present disclosure.

Referring to FIGS. 21 and 22, the display panel according to the embodiments of the present disclosure can include a thin film transistor and a light emitting element which are disposed on a substrate 400.

Specifically, a plurality of signal lines 1903 and 1909 and a light shield 1906 can be disposed on the substrate 400.

Each of the signal lines 1903 and 1909 of FIGS. 21 and 22 can be any one of the plurality of signal lines 201, 202, 203 and 204 shown in FIG. 7.

Each of the signal lines 1903 and 1909 can include a plurality of layers.

For example, one signal line 1903 can include a first layer 1901 and a second layer 1902 which is disposed on the first layer 1901, and the other signal line 1909 can include a fifth layer 1907 and a sixth layer 1908 which is disposed on the fifth layer 1907.

The light shield 1906 can also have a structure which includes a third layer 1904 and a fourth layer 1905 disposed on the third layer 1904.

The first layer 1901, the third layer 1904 and the fifth layer 1907 can include the same or substantially same material as each other, and the second layer 1902, the fourth layer 1905 and the sixth layer 1908 can include the same material as each other.

A first insulating layer 401 and a second insulating layer 402 can be sequentially disposed on the plurality of signal lines 1903 and 1909 and the light shield 1906.

A thin film transistor and a plurality of electrodes can be disposed on the second insulating layer 402.

Specifically, referring to FIGS. 21 and 22, in the active area of the display panel, a first active layer 1910, a second active layer 1911 and a third active layer 1912 can be disposed on the second insulating layer 402.

At least one active layer of the first to third active layers 1910, 1911 and 1912 can include an oxide semiconductor material.

The oxide semiconductor material, as a semiconductor material whose conductivity is controlled and band gap is adjusted by doping an oxide material, can generally be a transparent semiconductor material with a wide band gap.

For example, the oxide semiconductor material can include IGZO (indium gallium zinc oxide), ZnO (zinc oxide), IGO (indium gallium oxide), IZO (indium zinc oxide), CdO (cadmium oxide), InO (indium oxide), ZTO (zinc tin oxide), ZITO (zinc indium tin oxide), IGZTO (Indium gallium zinc tin oxide), etc.

A gate insulating layer 1920 can be disposed on the first active layer 1910 and the second active layer 1911.

Each of the first to third active layers 1910, 1911 and 1912 can be in a conductive state in an area where each of the first to third active layers 1910, 1911 and 1912 does not overlap the gate insulating layer 1920.

Namely, an area where each of the first to third active layers 1910, 1911 and 1912 overlaps the gate insulating layer 1920 can be a non-conductive area.

Referring to FIGS. 21 and 22, the third active layer 1912 can be made conductive to serve as an electrode. The third active layer 1912 can form a storage capacitor Cst together with the signal line which is disposed below the third active layer 1912.

Referring to FIGS. 21 and 22, the gate insulating layer 1920 can be disposed on a portion of the upper surface of the first active layer 1910 and a portion of the upper surface of the second active layer 1911.

In the active area, a source electrode 1931, a drain electrode 1932 and a gate electrode 1933 can be disposed on the gate insulating layer 1920.

However, the embodiments of the present disclosure are not limited thereto, and a source electrode 1931, a drain electrode 1932 and a gate electrode 1933 can be disposed on the gate insulating layer 1920.

In the non-active area of the display panel, an electrode can be disposed at the same or substantially same layer and include the same or substantially same material as the source electrode 1931, the drain electrode 1932 and the gate electrode 1933.

For example, as shown in FIGS. 21 and 22, a pad electrode 1935 can be disposed on the second insulating layer 402.

The source electrode 1931, the drain electrode 1932, the gate electrode 1933 and the pad electrode 1935 can be made of multiple layers.

For example, each of the source electrode 1931, the drain electrode 1932, the gate electrode 1933 and the pad electrode 1935 can be made of at least two layers. However, the embodiments of the present disclosure are not limited thereto, and at least one electrode can be made of a single layer.

A first layer 1931a of the source electrode 1931, a first layer 1932a of the drain electrode 1932, a first layer 1933a of the gate electrode 1933 and a first layer 1935a of the pad electrode 1935 can include the same or substantially same material, and a second layer 1931b of the source electrode 1931, a second layer 1932b of the drain electrode 1932, a second layer 1933b of the gate electrode 1933 and a second layer 1935b of the pad electrode 1935 can include the same or substantially same material. However, the embodiments of the present disclosure are not limited thereto, and can include different materials.

In the active area, a third insulating layer 403 can be disposed on the substrate 400 over which the source electrode 1931, the drain electrode 1932 and the gate electrode 1933 are disposed.

A color filter 280 can be disposed on the third insulating layer 403. The color filter 280 can overlap with a plurality of light emitting areas EA1 and EA2 which are defined in one subpixel.

A fourth insulating layer 404 can be disposed on the color filter 280.

In one subpixel, the fourth insulating layer 404 can include at least two holes and at least one recess portion 410.

For example, referring to FIGS. 21 and 22, the recess portion 410 of the fourth insulating layer 404 can overlap with a portion of the color filter 280.

However, the embodiments of the present disclosure are not limited thereto, and the recess portion 410 of the fourth insulating layer 404 can be disposed even in a subpixel in which the color filter 280 is not disposed.

Referring to FIGS. 21 and 22, one hole of the fourth insulating layer 404 can be provided over the source electrode 1931, and can overlap with a hole of the third insulating layer 403 to expose a portion of the upper surface of the source electrode 1931.

The other hole of the fourth insulating layer 404 can be defined in an area which overlaps with the third active layer 1912.

A first anode electrode 471 and a second anode electrode 472 can be disposed on the fourth insulating layer 404.

The first and second anode electrodes 471 and 472 can be disposed to be spaced apart from each other in a cross-sectional view with at least one recess portion 410 of the fourth insulating layer 404 interposed therebetween.

Although the cross-sectional view shows a structure in which only the second anode electrode 472 is electrically connected to the source electrode 1931 of the thin film transistor, the first anode electrode 471 can also be electrically connected to the thin film transistor to which the second anode electrode 472 is electrically connected.

Specifically, the anode electrode 270 disposed in one subpixel has a shape in which a plurality of holes are formed in the body of the anode electrode 270, and the plurality of holes can be areas corresponding to areas where the anode electrode 270 and the fourth insulating layer 404 do not overlap with each other in the opening of the bank 290.

Accordingly, the first and second anode electrodes 471 and 472 can be connected to each other in a plan view (are integrally formed), and can be electrically connected to the same thin film transistor.

Referring to FIGS. 21 and 22, the second anode electrode 472 can also be disposed in a portion of the hole which overlaps the third active layer 1912, among the holes provided in the fourth insulating layer 404.

Accordingly, the second anode electrode 472 can overlap the third active layer 1912 in the hole of the fourth insulating layer 404 to form the storage capacitor Cst.

In other words, each of the light shield 1906, the third active layer 1912 and the second anode electrode 472 can function as a storage capacitor electrode.

Referring to FIGS. 21 and 22, a bank 290 can be disposed on the substrate 400 over which the anode electrode 270 is disposed.

In one subpixel, the bank 290 can include one opening OP.

The one opening OP of the bank 290 can include a plurality of light emitting areas EA1 and EA2 and at least one non-light emitting area NEA1.

Specifically, the opening OP of the bank 290 can overlap with the first non-light emitting area NEA1, a first light emitting area EA1 and a second light emitting area EA2.

The first non-light emitting area NEA1 and the first light emitting area EA1 can correspond to an area where the anode electrode 270 does not overlap with the fourth insulating layer 404 in the opening OP of the bank 290.

In particular, the first non-light emitting area NEA1 can be an area corresponding to a flat portion of the recess portion 410 of the fourth insulating layer 404.

A portion of the first light emitting area EA1 can correspond to an inclined portion of the recess portion 410 of the fourth insulating layer 404.

The other portion of the first light emitting area EA1 can be an area which does not overlap the anode electrode 270 in a remaining area except for the recess portion 410 of the fourth insulating layer 404.

The second light emitting area EA2 can correspond to an area where the anode electrode 270 overlaps with the fourth insulating layer 404 in the opening OP of the bank 290.

Referring to FIGS. 21 and 22, a light emitting layer 492 and a cathode electrode 493 of the light emitting element can be sequentially disposed on the substrate 400 over which the bank 290 is disposed.

Referring to FIG. 21, each of the light emitting layer 492 and the cathode electrode 493 can include at least two steps in an area which corresponds to the opening OP of the bank 290.

Alternatively, as shown in FIG. 22, each of the light emitting layer 492 and the cathode electrode 493 can include a round-shaped depression DPS in an area which corresponds to the opening OP of the bank 290.

Referring to FIG. 21, due to the step of the cathode electrode 493 including a reflective electrode, light emitted from the light emitting element disposed between the anode electrode 270 and the cathode electrode 493 can be reflected by the step of the cathode electrode 493, and thus, light can be additionally extracted to the outside of the substrate 400.

Alternatively, referring to FIG. 22, due to the depression DPS of the cathode electrode 493 including a reflective electrode, light emitted from the light emitting element disposed between the anode electrode 270 and the cathode electrode 493 can be reflected by the depression DPS of the cathode electrode 493, and thus, light can be additionally extracted to the outside of the substrate 400.

In addition, due to the structural features, a phenomenon that light passes from one subpixel to another adjacent subpixel can be reduced, whereby it is possible to suppress a light leakage phenomenon and improve light extraction efficiency.

A brief description of the embodiments of the present disclosure described above is as follows.

A display panel according to embodiments of the present disclosure can include a substrate including a plurality of subpixels, an insulating layer disposed on the substrate, and including at least one recess portion in at least one subpixel, an anode electrode disposed on the insulating layer, and not overlapping the recess portion, a bank disposed on a portion of an upper surface of the anode electrode and the insulating layer, and having an opening in each of the plurality of subpixels, a light emitting layer disposed in the opening, and a cathode electrode disposed on the light emitting layer, in which each of the light emitting layer and the cathode electrode overlaps the anode electrode and the recess portion of the insulating layer in the opening, and has a step in the opening.

In the display panel according to the embodiments of the present disclosure, in at least one subpixel, the anode electrode can have a hole which overlaps the recess portion, in an area overlapping the opening.

In the display panel according to the embodiments of the present disclosure, the recess portion can include a flat portion and an inclined portion which extends from the flat portion, the insulating layer can include an upper surface which extends from the inclined portion, and the hole of the anode electrode can overlap with a portion of the upper surface.

In the display panel according to the embodiments of the present disclosure, the light emitting layer and the cathode electrode have a first step and a second step, in which the first step can be disposed at a boundary between the anode electrode and the upper surface, and in which the second step can be disposed at a boundary between the upper surface and the recess portion.

In the display panel according to the embodiments of the present disclosure, a distance from the upper surface of the insulating layer to an upper surface of the cathode electrode in an area where the first step is located can be longer than a distance from the upper surface of the insulating layer to the upper surface of the cathode electrode in an area where the second step is located.

In the display panel according to the embodiments of the present disclosure, the at least one subpixel can include a plurality of light emitting areas and at least one non-light emitting area in an area which overlaps with the opening.

In the display panel according to the embodiments of the present disclosure, an area corresponding to the flat portion of the recess portion can be a first non-light emitting area.

In the display panel according to the embodiments of the present disclosure, an area corresponding to the inclined portion of the recess portion and the upper surface of the insulating layer which extends from the inclined portion and does not overlap with the anode electrode can be a first light emitting area.

In the display panel according to the embodiments of the present disclosure, the first light emitting area can surround the first non-light emitting area.

In the display panel according to the embodiments of the present disclosure, an area which overlaps the insulating layer and the anode electrode in the opening can be a second light emitting area.

In the display panel according to the embodiments of the present disclosure, the second light emitting area can surround the first light emitting area.

In the display panel according to the embodiments of the present disclosure, luminance of the first light emitting area can be equal to or lower than luminance of the second light emitting area.

In the display panel according to the embodiments of the present disclosure, a third light emitting area disposed between the first light emitting area and the second light emitting area can be further included.

In the display panel according to the embodiments of the present disclosure, the first light emitting area can be an area corresponding to the inclined portion of the recess portion, and the third light emitting area can be an area corresponding to the upper surface of the insulating layer which extends from the inclined portion and does not overlap with the anode electrode.

In the display panel according to the embodiments of the present disclosure, luminance of the third light emitting area can be lower than luminance of the first and second light emitting areas.

In the display panel according to the embodiments of the present disclosure, an area which overlaps the bank can be a second non-light emitting area.

In the display panel according to the embodiments of the present disclosure, the cathode electrode can include a reflective electrode.

In the display panel according to the embodiments of the present disclosure, the display panel can further include a color filter disposed over the substrate in the at least one subpixel, and disposed under the insulating layer, in which the recess portion overlaps with a portion of the color filter.

In the display panel according to the embodiments of the present disclosure, the step of the light emitting layer and the cathode electrode can overlap with a portion of the color filter.

A display panel according to embodiments of the present disclosure can include a substrate including a plurality of subpixels, an insulating layer disposed on the substrate, and including at least one recess portion in at least one subpixel, an anode electrode disposed on the insulating layer, and not overlapping with the recess portion, a bank disposed on a portion of an upper surface of the anode electrode and the insulating layer, and having an opening in each of the plurality of subpixels, a light emitting layer disposed in the opening, and a cathode electrode disposed on the light emitting layer, in which each of the light emitting layer and the cathode electrode overlaps with the anode electrode and the recess portion of the insulating layer in the opening, and has a round-shaped depression in the opening.

In the display panel according to the embodiments of the present disclosure, one end of the recess portion and one end of the anode electrode can contact each other.

In the display panel according to the embodiments of the present disclosure, the depression of each of the light emitting layer and the cathode electrode can overlap with the recess portion.

A display device according to embodiments of the present disclosure can include a plurality of first non-light emitting areas, a plurality of first light emitting areas surrounding the first non-light emitting areas, a second light emitting area surrounding the first light emitting areas, and a second non-light emitting area surrounding the second light emitting area, in which the plurality of first non-light emitting areas, the plurality of first light emitting areas, the second light emitting area and the second non-light emitting area are disposed in one subpixel, and in which the plurality of first non-light emitting areas, the plurality of first light emitting areas and the second light emitting area are disposed in at least one of an opening of a bank or a boundary of the opening.

In the display device according to the embodiments of the present disclosure, the first light emitting area can be disposed between the second light emitting area and the second non-light emitting area in at least a portion of the boundary of the opening, and a boundary between the second light emitting area and the second non-light emitting area can have a concave-convex shape, a wavy shape, or a curly shape.

In the display device according to the embodiments of the present disclosure, at the boundary between the second light emitting area and the second non-light emitting area, each of a concave and a convex can have a polygonal shape.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the technical idea and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display panel comprising:
a plurality of subpixels disposed on a substrate;
an insulating layer disposed on the substrate, the insulating layer including at least one recess portion in at least one subpixel among the plurality of subpixels;
an anode electrode disposed on the insulating layer, the anode electrode not overlapping the recess portion;
a bank disposed on a portion of an upper surface of the anode electrode and the insulating layer, the bank having an opening in each of the plurality of subpixels;
a light emitting layer disposed in the opening; and
a cathode electrode disposed on the light emitting layer,
wherein each of the light emitting layer and the cathode electrode overlaps with the anode electrode and the recess portion of the insulating layer in the opening, and the cathode electrode has at least one stepped portion in the opening of the bank.

2. The display panel of claim 1, wherein the anode electrode is disposed in the at least one subpixel and has a hole overlapping with the recess portion of the insulating layer, in an area overlapping with the opening of the bank.

3. The display panel of claim 2, wherein the recess portion includes a flat portion and an inclined portion extending from the flat portion,
wherein the insulating layer includes an upper surface extending from the inclined portion, and
wherein the hole of the anode electrode overlaps with a portion of the upper surface of the insulating layer.

4. The display panel of claim 3, wherein the at least one stepped portion of the cathode electrode includes a first stepped portion and a second stepped portion,
wherein the first stepped portion is disposed at a boundary between the anode electrode and the upper surface of the insulating layer, and
wherein the second stepped portion is disposed at a boundary between the upper surface of the insulating layer and the recess portion.

5. The display panel of claim 4, wherein a distance from the upper surface of the insulating layer to an upper surface of the cathode electrode in an area where the first stepped portion is located is longer than a distance from the upper surface of the insulating layer to the upper surface of the cathode electrode in an area where the second stepped portion is located.

6. The display panel of claim 1, wherein the at least one subpixel includes a plurality of light emitting areas and at least one non-light emitting area in an area overlapping with the opening of the bank.

7. The display panel of claim 6, wherein an area corresponding to a flat portion of the recess portion is a first non-light emitting area.

8. The display panel of claim 6, wherein an area corresponding to an inclined portion of the recess portion and the upper surface of the insulating layer extending from the inclined portion and does not overlap with the anode electrode is a first light emitting area.

9. The display panel of claim 8, wherein the first light emitting area surrounds a first non-light emitting area.

10. The display panel of claim 6, wherein an area overlapping with the insulating layer and the anode electrode in the opening of the bank is a second light emitting area.

11. The display panel of claim 10, wherein the second light emitting area surrounds a first light emitting area.

12. The display panel of claim 10, wherein luminance of a first light emitting area is equal to or lower than luminance of the second light emitting area.

13. The display panel of claim 10, further comprising:
a third light emitting area disposed between a first light emitting area and the second light emitting area.

14. The display panel of claim 13, wherein the first light emitting area corresponds to a inclined portion of the recess portion, and
wherein the third light emitting area corresponds to the upper surface of the insulating layer extending from the inclined portion, and the third light emitting area does not overlap with the anode electrode.

15. The display panel of claim 13, wherein luminance of the third light emitting area is lower than luminance of the first and second light emitting areas.

16. The display panel of claim 1, wherein an area overlapping with the bank is a second non-light emitting area.

17. The display panel of claim 1, wherein the cathode electrode includes a reflective electrode.

18. The display panel of claim 1, further comprising:
a color filter disposed over the substrate in the at least one subpixel, and disposed under the insulating layer,
wherein the recess portion overlaps with a portion of the color filter.

19. The display panel of claim 18, wherein the at least one stepped portion of the cathode electrode overlaps with a portion of the color filter.

20. A display panel comprising:
a plurality of subpixels disposed on a substrate;
an insulating layer disposed on the substrate, the insulating layer including at least one recess portion in at least one subpixel among the plurality of subpixels;
an anode electrode disposed on the insulating layer, the anode electrode not overlapping with the recess portion;
a bank disposed on a portion of an upper surface of the anode electrode and the insulating layer, the bank having an opening in each of the plurality of subpixels;
a light emitting layer disposed in the opening; and
a cathode electrode disposed on the light emitting layer,
wherein each of the light emitting layer and the cathode electrode overlaps with the anode electrode and the recess portion of the insulating layer in the opening, and the cathode electrode has a depression in the opening, the depression having a rounded shape or a curved shape.

21. The display panel of claim 20, wherein one end of the recess portion and one end of the anode electrode contact each other.

22. The display panel of claim 20, wherein the depression of the cathode electrode overlaps with the recess portion in the insulating layer.

23. A display device comprising:
a plurality of first non-light emitting areas;
a plurality of first light emitting areas surrounding the first non-light emitting areas;
a second light emitting area surrounding each of plurality of the first light emitting areas; and
a second non-light emitting area surrounding the second light emitting area,
wherein the plurality of first non-light emitting areas, the plurality of first light emitting areas, the second light emitting area and the second non-light emitting area are disposed in a same subpixel, and
wherein the plurality of first non-light emitting areas, the plurality of first light emitting areas and the second light emitting area are disposed in at least one of an opening of a bank or a boundary of the opening of the bank.

24. The display device of claim 23, wherein each of the plurality of first light emitting areas is disposed between the second light emitting area and the second non-light emitting area in at least a portion of the boundary of the opening, and a boundary between the second light emitting area and the second non-light emitting area has a concave-convex shape, a wavy shape or a curvy shape.

25. The display device of claim 24, wherein the boundary between the second light emitting area and the second non-light emitting area has a polygonal shape.

26. A display panel comprising:
a subpixel disposed on a substrate, the subpixel including an anode electrode, a light emitting layer and a cathode electrode, wherein the anode electrode includes a first anode electrode portion and a second anode electrode portion;
an insulating layer disposed between the anode electrode and the substrate;
a recessed portion in the insulating layer being disposed between the first anode portion and the second anode portion,
wherein the cathode electrode includes a lower cathode electrode portion overlapping with the recessed portion in the insulating layer.

27. The display panel of claim 26, wherein cathode electrode includes a reflective material, and
wherein the lower cathode electrode portion is configured to reflect light emitted from the light emitting layer to pass between the first anode portion and the second anode portion and travel out of the display panel.

28. The display panel of claim 26, wherein a portion of the light emitting layer is disposed in the recessed portion in the insulating layer,
wherein the light emitting layer includes a depressed portion overlapping with the recessed portion in the insulating layer, and
wherein a portion of the cathode electrode is disposed in the depressed portion in the light emitting layer.

29. The display panel of claim 26, wherein the cathode electrode includes a first stepped portion and a second stepped portion, and
wherein the first stepped portion of the cathode electrode overlaps with an inclined side surface of the recessed portion in the insulating layer, and the second stepped portion of the cathode electrode overlaps with a flat bottom surface of the recessed portion in the insulating layer.
